(19) United States
(12) Patent Application Publication
(10) Pub. No.: US 2025/0359452 A1
(43) Pub. Date: Nov. 20, 2025

(54) DISPLAY DEVICE

(71) Applicant: SEMICONDUCTOR ENERGY LABORATORY CO., LTD., Atsugi-shi (JP)

(72) Inventors: Takuya KAWATA, Atsugi (JP); Kunio KIMURA, Zama (JP)

(21) Appl. No.: 19/183,012

(22) Filed: Apr. 18, 2025

(30) Foreign Application Priority Data
May 17, 2024 (JP) 2024-081012

(51) Int. Cl. H10K 59/32; H10K 59/35; H10K 101/00

(52) U.S. Cl. CPC H10K 59/32; H10K 59/35; H10K 2101/90

(57) ABSTRACT

A display device with reduced manufacturing cost is provided. The display device includes first to third subpixels emitting light of different colors. The first subpixel includes a first coloring layer and a first light-emitting device. The second subpixel includes a second coloring layer and a second light-emitting device. The third subpixel includes a third light-emitting device. The first light-emitting device includes first and second light-emitting layers between a pair of electrodes and includes a first intermediate layer between the first and second light-emitting layers. The first and second light-emitting layers each include a layer including a blue-light-emitting substance and a layer including a red-light-emitting substance. The second light-emitting device includes third and fourth light-emitting layers between a pair of electrodes and includes a second intermediate layer between the third and fourth light-emitting layers. The third and fourth light-emitting layers each include a layer including a blue-light-emitting substance and a layer including a red-light-emitting substance. The third light-emitting device includes fifth and sixth light-emitting layers between a pair of electrodes and includes a third intermediate layer between the fifth and sixth light-emitting layers. The fifth and sixth light-emitting layers each include a green-light-emitting substance.

### BACKGROUND OF THE INVENTION

### 1. Field of the Invention

One embodiment of the present invention relates to a display device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting apparatus, a lighting device, a power storage device, a memory device, an image capturing device, a driving method thereof, and a manufacturing method thereof.

### 2. Description of the Related Art

Light-emitting devices (organic EL devices) that include organic compounds and utilize electroluminescence (EL) have been put to practical use. In the basic structure of such light-emitting devices, an organic compound layer (EL layer) including a light-emitting material is sandwiched between a pair of electrodes. Carriers are injected by application of voltage to the device, and recombination energy of the carriers is used to obtain light emission from the light-emitting material.

Such light-emitting devices are of self-luminous type and thus have advantages over liquid crystal devices such as high visibility and no need for backlight when used in pixels of a display device, and are suitable as devices used in flat panel displays. Display devices that include such light-emitting devices are also highly advantageous in that they can be thin and lightweight. Another feature of such light-emitting devices is that they have an extremely fast response speed.

Display devices including light-emitting devices are suitable for a variety of electronic devices, and progress has been made in research and development aiming at improving the characteristics of light-emitting devices. In particular, what is called a tandem light-emitting device, in which a plurality of light-emitting units are stacked, has been attracting attention because of its high emission efficiency. Patent Documents 1 and 2 each disclose a tandem light-emitting device manufactured by a separate coloring method.

### REFERENCES

[Patent Document 1] Japanese Published Patent Application No. 2005-317548
[Patent Document 2] Japanese Published Patent Application No. 2023-161850

### SUMMARY OF THE INVENTION

The process of manufacturing a tandem light-emitting device by a separate coloring method is disadvantageously complicated to have a larger number of steps. Thus, a display device whose pixel includes a tandem light-emitting device manufactured by a separate coloring method has problems such as an increase in manufacturing cost and a decrease in manufacturing yield.

In view of the above, an object of one embodiment of the present invention is to provide a display device the manufacturing process of which is simplified. Another object of one embodiment of the present invention is to provide a display device with reduced manufacturing cost. Another object of one embodiment of the present invention is to provide an inexpensive display device. Another object of one embodiment of the present invention is to provide a display device with low power consumption. Another object of one embodiment of the present invention is to provide a novel display device.

Note that the description of these objects does not preclude the existence of other objects. In one embodiment of the present invention, there is no need to achieve all of these objects. Other objects will be apparent from and can be derived from the description of the specification, the drawings, the claims, and the like.

One embodiment of the present invention is a display device which includes a first subpixel, a second subpixel, and a third subpixel emitting light of different colors and in which the first subpixel includes a first coloring layer and a first light-emitting device; the second subpixel includes a second coloring layer and a second light-emitting device; the third subpixel includes a third light-emitting device; the first light-emitting device includes a first light-emitting layer and a second light-emitting layer between a pair of electrodes and includes a first intermediate layer between the first light-emitting layer and the second light-emitting layer; the first light-emitting layer and the second light-emitting layer each include a layer including a blue-light-emitting substance and a layer including a red-light-emitting substance; the second light-emitting device includes a third light-emitting layer and a fourth light-emitting layer between a pair of electrodes and includes a second intermediate layer between the third light-emitting layer and the fourth light-emitting layer; the third light-emitting layer and the fourth light-emitting layer each include a layer including a blue-light-emitting substance and a layer including a red-light-emitting substance; the third light-emitting device includes a fifth light-emitting layer and a sixth light-emitting layer between a pair of electrodes and includes a third intermediate layer between the fifth light-emitting layer and the sixth light-emitting layer; and the fifth light-emitting layer and the sixth light-emitting layer each include a green-light-emitting substance. It is preferable that the blue-light-emitting substance be a fluorescent substance and the red-light-emitting substance be a phosphorescent substance. It is preferable that the layer including the blue-light-emitting substance include a first host material and a T₁ level of the first host material and a T₁ level of the blue-light-emitting substance be higher than a T₁ level of the red-light-emitting substance.

Another embodiment of the present invention is a display device which includes a first subpixel and a second subpixel emitting light of different colors; the first subpixel includes a first coloring layer and a first light-emitting device; the second subpixel includes a second coloring layer and a second light-emitting device; the first light-emitting device includes a first light-emitting layer, a second light-emitting layer, a third light-emitting layer, a fourth light-emitting layer, and a first intermediate layer between a pair of electrodes; the first light-emitting layer is in contact with the second light-emitting layer; the third light-emitting layer is in contact with the fourth light-emitting layer; the first intermediate layer is between the first light-emitting layer and the third light-emitting layer and is between the second light-emitting layer and the fourth light-emitting layer; the second light-emitting device includes a fifth light-emitting layer, a sixth light-emitting layer, a seventh light-emitting layer, an eighth light-emitting layer, and a second intermediate layer between a pair of electrodes; the fifth light-emitting layer is in contact with the sixth light-emitting layer; the seventh light-emitting layer is in contact with the eighth light-emitting layer; the second intermediate layer is between the fifth light-emitting layer and the seventh light-emitting layer and is between the sixth light-emitting layer and the eighth light-emitting layer; the first light-emitting layer and the fifth light-emitting layer include a first light-emitting substance; the second light-emitting layer and the sixth light-emitting layer include a second light-emitting substance; the third light-emitting layer and the seventh light-emitting layer include the first light-emitting substance; and the fourth light-emitting layer and the eighth light-emitting layer include the second light-emitting substance. It is preferable that the first light-emitting substance be a blue-light-emitting substance and the second light-emitting substance be a red-light-emitting substance. It is preferable that an emission wavelength of one of the first light-emitting substance and the second light-emitting substance be greater than or equal to 1.18 times and less than or equal to 1.88 times an emission wavelength of the other of the first light-emitting substance and the second light-emitting substance.

Another embodiment of the present invention is a display device which includes a first subpixel, a second subpixel, and a third subpixel emitting light of different colors and in which the first subpixel includes a first coloring layer and a first light-emitting device; the second subpixel includes a second coloring layer and a second light-emitting device; the third subpixel includes a third light-emitting device; the first light-emitting device includes a first light-emitting layer, a second light-emitting layer, a third light-emitting layer, a fourth light-emitting layer, and a first intermediate layer between a pair of electrodes; the first light-emitting layer is in contact with the second light-emitting layer; the third light-emitting layer is in contact with the fourth light-emitting layer; the first intermediate layer is between the first light-emitting layer and the third light-emitting layer and is between the second light-emitting layer and the fourth light-emitting layer; the second light-emitting device includes a fifth light-emitting layer, a sixth light-emitting layer, a seventh light-emitting layer, an eighth light-emitting layer, and a second intermediate layer between a pair of electrodes; the fifth light-emitting layer is in contact with the sixth light-emitting layer; the seventh light-emitting layer is in contact with the eighth light-emitting layer; the second intermediate layer is between the fifth light-emitting layer and the seventh light-emitting layer and is between the sixth light-emitting layer and the eighth light-emitting layer; the third light-emitting device includes a ninth light-emitting layer, a tenth light-emitting layer, and a third intermediate layer between a pair of electrodes; the third intermediate layer is between the ninth light-emitting layer and the tenth light-emitting layer; the first light-emitting layer and the fifth light-emitting layer include a first light-emitting substance; the second light-emitting layer and the sixth light-emitting layer include a second light-emitting substance; the third light-emitting layer and the seventh light-emitting layer include the first light-emitting substance; the fourth light-emitting layer and the eighth light-emitting layer include the second light-emitting substance; and the ninth light-emitting layer and the tenth light-emitting layer include a third light-emitting substance. It is preferable that the first light-emitting substance be a blue-light-emitting substance, the second light-emitting substance be a red-light-emitting substance, and the third light-emitting substance be a green-light-emitting substance. It is preferable that an emission wavelength of one of the first light-emitting substance and the second light-emitting substance be greater than or equal to 1.18 times and less than or equal to 1.88 times an emission wavelength of the other of the first light-emitting substance and the second light-emitting substance.

Another embodiment of the present invention is a display device having any of the above structures in which the first light-emitting substance is a fluorescent substance and the second light-emitting substance is a phosphorescent substance.

Another embodiment of the present invention is a display device having any of the above structures in which the first light-emitting substance is a fluorescent substance, the second light-emitting substance is a phosphorescent substance, the first light-emitting layer includes a first host material, and a T₁ level of the first host material and a T₁ level of the first light-emitting substance are higher than a T₁ level of the second light-emitting substance.

Another embodiment of the present invention is a display device having any of the above structures in which the first intermediate layer and the second intermediate layer each include an organic compound and an alkali metal or an alkaline earth metal.

Another embodiment of the present invention is a display device having any of the above structures in which the first intermediate layer and the second intermediate layer include the same organic compound and the same alkali metal or the same alkaline earth metal.

According to one embodiment of the present invention, a display device the manufacturing process is simplified can be provided. According to one embodiment of the present invention, a display device with reduced manufacturing cost can be provided. According to one embodiment of the present invention, an inexpensive display device can be provided. According to one embodiment of the present invention, a display device with low power consumption can be provided. According to one embodiment of the present invention, a novel display device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a top view illustrating a structure of a display device of an embodiment and FIG. 1B is a cross-sectional view illustrating the structure of the display device of the embodiment;

FIGS. 2A and 2B are cross-sectional views illustrating structures of a display device of an embodiment;

FIG. 3 is an energy diagram of an embodiment;

FIGS. 4A and 4B are cross-sectional views illustrating structures of a display device of an embodiment;

FIGS. 5A and 5B are cross-sectional views illustrating structures of a display device of an embodiment;

FIGS. 6A and 6B are cross-sectional views illustrating structures of a display device of an embodiment;

FIGS. 7A to 7D are cross-sectional views illustrating an example of a method for manufacturing a display device;

FIGS. 8A to 8D are cross-sectional views illustrating an example of a method for manufacturing a display device;

FIGS. 9A to 9C are cross-sectional views illustrating an example of a method for manufacturing a display device;

FIGS. 10A to 10E each illustrate a light-emitting device;

FIGS. 11A and 11B are perspective views illustrating an example of a display device;

FIG. 12 is a cross-sectional view illustrating an example of a display device;

FIGS. 13A to 13D illustrate examples of electronic devices;

FIGS. 14A to 14F illustrate examples of electronic devices;

FIGS. 15A to 15G illustrate examples of electronic devices; and

FIGS. 16A to 16G are top views illustrating structure examples of pixels.

### DETAILED DESCRIPTION OF THE INVENTION

Embodiments of the present invention will be described in detail below with reference to the drawings. Note that the present invention is not limited to the following description, and the modes and details of the present invention can be modified in various ways without departing from the spirit and scope of the present invention. Therefore, the present invention should not be construed as being limited to the description in the following embodiments.

Note that the position, size, range, or the like of each component illustrated in drawings and the like is not accurately represented in some cases for easy understanding. Therefore, the disclosed invention is not necessarily limited to the position, size, range, or the like disclosed in the drawings and the like.

Ordinal numbers such as “first” and “second” in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those used to specify one embodiment of the present invention.

In the description of structures of the present invention in this specification and the like with reference to the drawings, the same components in different drawings are denoted by the same reference numeral in some cases.

In this specification and the like, the terms “film” and “layer” can be interchanged with each other. For example, the term “conductive layer” can be changed into the term “conductive film” in some cases. For another example, the term “insulating film” can be changed into the term “insulating layer” in some cases.

### Embodiment 1

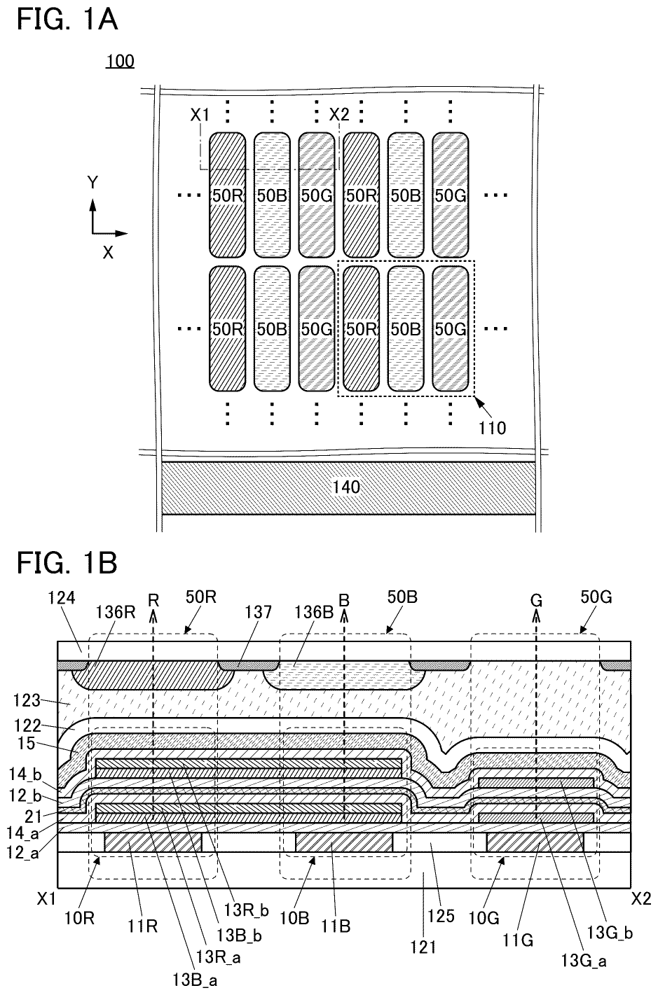

In this embodiment, a display device of one embodiment of the present invention will be described with reference to FIGS. 1A and 1B, FIGS. 2A and 2B, FIG. 3, FIGS. 4A and 4B, FIGS. 5A and 5B, and FIGS. 6A and 6B.

FIG. 1A is a top view of a display device 100 of one embodiment of the present invention. The display device 100 includes a display portion in which a plurality of pixels 110 are arranged, and a connection portion 140 outside the display portion. A plurality of subpixels are arranged in a matrix in the display portion. FIG. 1A illustrates subpixels arranged in two rows and six columns, which form the pixels 110 in two rows and two columns. The connection portion 140 can also be referred to as a cathode contact portion. Although not illustrated, each subpixel includes a circuit for driving the subpixel. The circuit includes a transistor and is connected to a light-emitting device included in the subpixel.

The top surface shape of the subpixel illustrated in FIG. 1A corresponds to the top surface shape of a light-emitting region. In this specification and the like, a top surface shape refers to a shape in a plan view, i.e., a shape seen from above. Examples of the top surface shape of the subpixel include polygons such as a triangle, a tetragon (including a rectangle, a rhombus, and a square), and a pentagon; these polygons with rounded corners; an ellipse; and a circle.

The range of the circuit layout for forming the subpixels is not limited to the range of the subpixels illustrated in FIG. 1A, and the components of the circuit may be located outside the range of the subpixels. For example, some or all of the transistors of a subpixel 50R illustrated in FIG. 1A may be located outside the range of the subpixel 50R. The transistors of the subpixel 50R may be located within the range of the subpixel 50R, the range of a subpixel 50G, or the range of a subpixel 50B illustrated in FIG. 1A, or may be located in two or more of these ranges.

Although the subpixels 50R, 50B, and 50G have the same or substantially the same aperture ratio (also referred to as size or size of a light-emitting region) in FIG. 1A, one embodiment of the present invention is not limited thereto. The aperture ratio of each of the subpixels 50R, 50B, and 50G can be determined as appropriate. The subpixels 50R, 50B, and 50G may have different aperture ratios, or two or more of the subpixels 50R, 50B, and 50G may have the same or substantially the same aperture ratio.

The pixel 110 illustrated in FIG. 1A employs stripe arrangement. The pixel 110 illustrated in FIG. 1A includes three subpixels, the subpixels 50R, 50B, and 50G. The subpixels 50R, 50B, and 50G are different in emission color. Examples of the emission colors of the subpixels 50R, 50B, and 50G include red, blue, and green.

In this specification and the like, the row direction, the column direction, and the depth direction are sometimes referred to as the X direction, the Y direction, and the Z direction, respectively. FIG. 1A illustrates an example where subpixels of different colors are arranged in the X direction and subpixels of the same color are arranged in the Y direction.

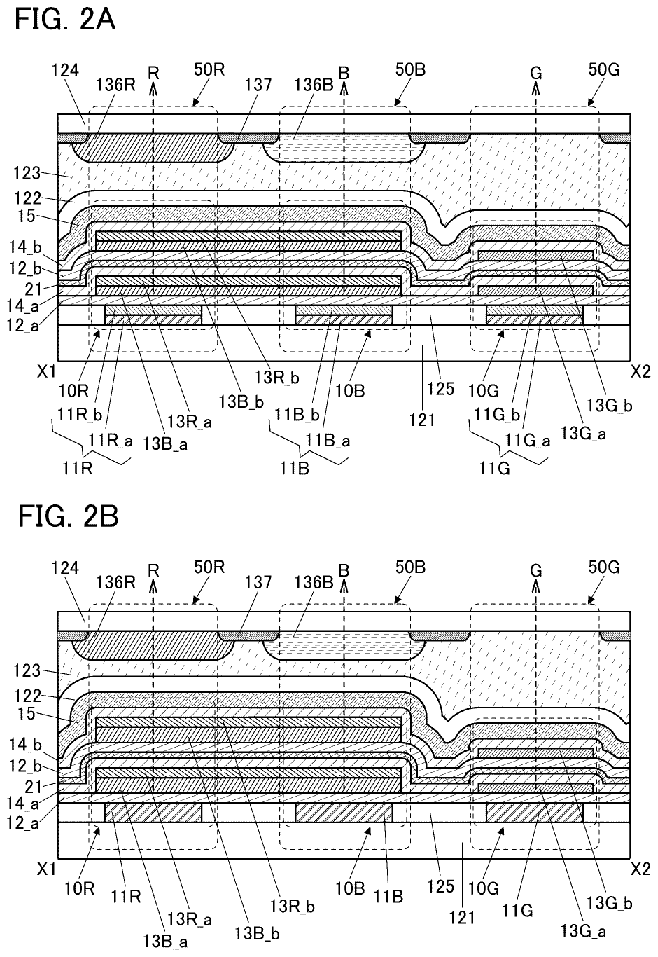

FIG. 1B is a cross-sectional view along the dashed-dotted line X1-X2 in FIG. 1A. FIGS. 2A and 2B, FIGS. 4A and 4B, FIGS. 5A and 5B, and FIGS. 6A and 6B illustrate variation examples of the cross-sectional view along the dashed-dotted line X1-X2 in FIG. 1A.

In the display device 100, a light-emitting device 10R, a light-emitting device 10B, and a light-emitting device 10G are provided over a layer 121 including transistors (not illustrated), and a protective layer 122 is provided to cover these light-emitting devices. A substrate 124 provided with a coloring layer 136R and a coloring layer 136B is attached onto the protective layer 122 with a resin layer 123. An insulating layer 125 is provided in a region between anodes of adjacent light-emitting devices. A black matrix 137 is provided in a region between adjacent coloring layers.

In the display device 100, the subpixel 50R includes the light-emitting device 10R and the coloring layer 136R overlapping with the light-emitting device 10R, the subpixel 50B includes the light-emitting device 10B and the coloring layer 136B overlapping with the light-emitting device 10B, and the subpixel 50G includes the light-emitting device 10G. In the display device 100, although the light-emitting device 10R and the light-emitting device 10B have similar structures and thus emit light of the same color, the subpixel 50R and the subpixel 50B can emit light of different colors by being provided with coloring layers that transmit light of different colors. The light-emitting device 10G has a structure and an emission color different from those of the light-emitting devices 10R and 10B, and thus, the subpixel 50G can emit light of a color different from the colors of light emitted by the subpixel 50R and the subpixel 50B, without a coloring layer.

The display device of one embodiment of the present invention preferably has a top-emission structure in which light is emitted in a direction opposite to the substrate where the light-emitting devices are formed.

The layer 121 can have a stacked-layer structure in which a plurality of transistors (not illustrated) are provided over a substrate and an insulating layer is provided to cover these transistors, for example. The layer 121 may have a recess portion in a region not overlapping with the light-emitting device. For example, an insulating layer being the outermost surface of the layer 121 may have a recess portion. Structure examples of the layer 121 will be described later in Embodiment 4.

As illustrated in FIG. 1B, the tandem light-emitting devices 10R, 10B, and 10G in the display device 100 are provided in the following manner: an anode 11R, an anode 11B, and an anode 11G are provided over the layer 121; a first hole-injection/transport layer 12_a is provided over the anode 11R, the anode 11B, and the anode 11G; a first light-emitting layer 13B_a is provided in a position being over the first hole-injection/transport layer 12_a and overlapping with the anodes 11R and 11B; a second light-emitting layer 13R_a is provided in a position being over the first light-emitting layer 13B_a and overlapping with the anodes 11R and 11B; a first light-emitting layer 13G_a is provided in a position being over the first hole-injection/transport layer 12_a and overlapping with the anode 11G; a first electron-injection/transport layer 14_a is provided over the second light-emitting layer 13R_a and the first light-emitting layer 13G_a; an intermediate layer 21 is provided over the first electron-injection/transport layer 14_a; a second hole-injection/transport layer 12_b is provided over the intermediate layer 21; a third light-emitting layer 13B_b is provided in a position being over the second hole-injection/transport layer 12_b and overlapping with the anodes 11R and 11B; a fourth light-emitting layer 13R_b is provided in a position being over the third light-emitting layer 13B_b and overlapping with the anodes 11R and 11B; a second light-emitting layer 13G_b is provided in a position being over the second hole-injection/transport layer 12_b and overlapping with the anode 11G; a second electron-injection/transport layer 14_b is provided over the fourth light-emitting layer 13R_b and the second light-emitting layer 13G_b; and a cathode 15 is formed over the second electron-injection/transport layer 14_b. Note that the first hole-injection/transport layer 12_a and the second hole-injection/transport layer 12_b each preferably have a stacked-layer structure; for example, the first hole-injection/transport layer 12_a and the second hole-injection/transport layer 12_b each preferably have a stacked-layer structure in which a hole-injection layer and a hole-transport layer are stacked in this order from the anode side. The first electron-injection/transport layer 14_a and the second electron-injection/transport layer 14_b each preferably have a stacked-layer structure; for example, the first electron-injection/transport layer 14_a and the second electron-injection/transport layer 14_b each preferably have a stacked-layer structure in which an electron-transport layer and an electron-injection layer are stacked in this order from the light-emitting layer side.

Each of the first hole-injection/transport layer 12_a, the second hole-injection/transport layer 12_b, the intermediate layer 21, the first electron-injection/transport layer 14_a, the second electron-injection/transport layer 14_b, and the cathode 15 is preferably a layer shared by the light-emitting devices 10R, 10B, and 10G (hereinafter sometimes referred to as a common layer). When these layers are common layers, the manufacturing process of the display device 100 can be simplified, reducing the cost of the display device 100.

The first light-emitting layer 13B_a, the second light-emitting layer 13R_a, the third light-emitting layer 13B_b, and the fourth light-emitting layer 13R_b are each preferably a layer formed in the light-emitting devices 10R and 10B by a vacuum evaporation method using a metal mask. The first light-emitting layer 13G_a and the second light-emitting layer 13G_b are each preferably a layer formed in the light-emitting device 10G by a vacuum evaporation method using a metal mask. Note that the first light-emitting layer 13B_a, the second light-emitting layer 13R_a, the third light-emitting layer 13B_b, and the fourth light-emitting layer 13R_b are each preferably a layer shared by the light-emitting devices 10R and 10B. When these layers are shared by the light-emitting devices 10R and 10B, the manufacturing process of the display device 100 can be simplified, reducing the cost of the display device 100.

The light-emitting device 10R includes the first light-emitting layer 13B_a, the second light-emitting layer 13R_a, the third light-emitting layer 13B_b, the fourth light-emitting layer 13R_b, and the intermediate layer 21 between the anode 11R and the cathode 15. The intermediate layer 21 is located between the first light-emitting layer 13B_a and the third light-emitting layer 13B_b and is located between the second light-emitting layer 13R_a and the fourth light-emitting layer 13R_b. The first light-emitting layer 13B_a and the second light-emitting layer 13R_a are preferably in contact with each other. Alternatively, the first light-emitting layer 13B_a and the second light-emitting layer 13R_a are preferably stacked with a buffer layer therebetween. The third light-emitting layer 13B_b and the fourth light-emitting layer 13R_b are preferably in contact with each other. Alternatively, the third light-emitting layer 13B_b and the fourth light-emitting layer 13R_b are preferably stacked with a buffer layer therebetween. The light-emitting device 10R includes the first hole-injection/transport layer 12_a, the first electron-injection/transport layer 14_a, the second hole-injection/transport layer 12_b, and the second electron-injection/transport layer 14_b. The first hole-injection/transport layer 12_a is located between the anode 11R and the first light-emitting layer 13B_a and is located between the anode 11R and the second light-emitting layer 13R_a. The first electron-injection/transport layer 14_a is located between the first light-emitting layer 13B_a and the intermediate layer 21 and is located between the second light-emitting layer 13R_a and the intermediate layer 21. The second hole-injection/transport layer 12_b is located between the intermediate layer 21 and the third light-emitting layer 13B_b and is located between the intermediate layer 21 and the fourth light-emitting layer 13R_b. The second electron-injection/transport layer 14_b is located between the third light-emitting layer 13B_b and the cathode 15 and is located between the fourth light-emitting layer 13R_b and the cathode 15.

The light-emitting device 10B includes the first light-emitting layer 13B_a, the second light-emitting layer 13R_a, the third light-emitting layer 13B_b, the fourth light-emitting layer 13R_b, and the intermediate layer 21 between the anode 11B and the cathode 15. The intermediate layer 21 is located between the first light-emitting layer 13B_a and the third light-emitting layer 13B_b and is located between the second light-emitting layer 13R_a and the fourth light-emitting layer 13R_b. The first light-emitting layer 13B_a and the second light-emitting layer 13R_a are preferably in contact with each other. Alternatively, the first light-emitting layer 13B_a and the second light-emitting layer 13R_a are preferably stacked with a buffer layer therebetween. The third light-emitting layer 13B_b and the fourth light-emitting layer 13R_b are preferably in contact with each other. Alternatively, the third light-emitting layer 13B_b and the fourth light-emitting layer 13R_b are preferably stacked with a buffer layer therebetween. The light-emitting device 10B includes the first hole-injection/transport layer 12_a, the first electron-injection/transport layer 14_a, the second hole-injection/transport layer 12_b, and the second electron-injection/transport layer 14_b. The first hole-injection/transport layer 12_a is located between the anode 11B and the first light-emitting layer 13B_a and is located between the anode 11B and the second light-emitting layer 13R_a. The first electron-injection/transport layer 14_a is located between the first light-emitting layer 13B_a and the intermediate layer 21 and is located between the second light-emitting layer 13R_a and the intermediate layer 21. The second hole-injection/transport layer 12_b is located between the intermediate layer 21 and the third light-emitting layer 13B_b and is located between the intermediate layer 21 and the fourth light-emitting layer 13R_b. The second electron-injection/transport layer 14_b is located between the third light-emitting layer 13B_b and the cathode 15 and is located between the fourth light-emitting layer 13R_b and the cathode 15.

In the light-emitting devices 10R and 10B, the first light-emitting layer 13B_a and the second light-emitting layer 13R_a include light-emitting substances emitting light of different colors. The third light-emitting layer 13B_b and the fourth light-emitting layer 13R_b include light-emitting substances emitting light of different colors. The first light-emitting layer 13B_a and the third light-emitting layer 13B_b include light-emitting substances emitting light of the same color. The second light-emitting layer 13R_a and the fourth light-emitting layer 13R_b include light-emitting substances emitting light of the same color. When the light-emitting devices 10R and 10B include the above-described combination of the first light-emitting layer 13B_a, the second light-emitting layer 13R_a, the third light-emitting layer 13B_b, and the fourth light-emitting layer 13R_b, the light-emitting devices 10R and 10B can emit light of a color obtained by mixing a color derived from the light-emitting substances of the first light-emitting layer 13B_a and the third light-emitting layer 13B_b and a color derived from the light-emitting substances of the second light-emitting layer 13R_a and the fourth light-emitting layer 13R_b. In the display device 100, when the coloring layer 136R overlapping with the light-emitting device 10R and the coloring layer 136B overlapping with the light-emitting device 10B transmit light of different colors, the subpixel 50R and the subpixel 50B can emit light of different colors.

When the first light-emitting layer 13B_a and the third light-emitting layer 13B_b include the same light-emitting substance and the second light-emitting layer 13R_a and the fourth light-emitting layer 13R_b include the same light-emitting substance in the light-emitting devices 10R and 10B, the display device 100 can be easily manufactured, and the cost of the display device 100 can be reduced.

In the case where the first light-emitting layer 13B_a and the third light-emitting layer 13B_b include a blue-light-emitting substance and the second light-emitting layer 13R_a and the fourth light-emitting layer 13R_b include a red-light-emitting substance, the light-emitting devices 10R and 10B can emit light of a magenta color obtained by mixing blue and red. In this case, when the coloring layer 136R overlapping with the light-emitting device 10R includes a material that transmits red light and the coloring layer 136B overlapping with the light-emitting device 10B includes a material that transmits blue light, the subpixel 50R can be a red subpixel and the subpixel 50B can be a blue subpixel.

For another example, in the case where the first light-emitting layer 13B_a and the third light-emitting layer 13B_b include a green-light-emitting substance and the second light-emitting layer 13R_a and the fourth light-emitting layer 13R_b include a red-light-emitting substance, the light-emitting devices 10R and 10B can emit light of a yellow color obtained by mixing green and red. In this case, when the coloring layer 136R overlapping with the light-emitting device 10R includes a material that transmits red light and the coloring layer 136B overlapping with the light-emitting device 10B includes a material that transmits green light, the subpixel 50R can be a red subpixel and the subpixel 50B can be a green subpixel.

For another example, in the case where the first light-emitting layer 13B_a and the third light-emitting layer 13B_b include a blue-light-emitting substance and the second light-emitting layer 13R_a and the fourth light-emitting layer 13R_b include a green-light-emitting substance, the light-emitting devices 10R and 10B can emit light of a cyan color obtained by mixing blue and green. In this case, when the coloring layer 136R overlapping with the light-emitting device 10R includes a material that transmits green light and the coloring layer 136B overlapping with the light-emitting device 10B includes a material that transmits blue light, the subpixel 50R can be a green subpixel and the subpixel 50B can be a blue subpixel.

In the light-emitting devices 10R and 10B illustrated in FIG. 1B, the first light-emitting layer 13B_a is located closer to the anodes 11R and 11B than the second light-emitting layer 13R_a, the second light-emitting layer 13R_a is located closer to the cathode 15 than the first light-emitting layer 13B_a, the third light-emitting layer 13B_b is located closer to the anodes 11R and 11B than the fourth light-emitting layer 13R_b, and the fourth light-emitting layer 13R_b is located closer to the cathode 15 than the third light-emitting layer 13B_b; however, one embodiment of the present invention is not limited thereto. The first light-emitting layer 13B_a may be located closer to the cathode 15, the second light-emitting layer 13R_a may be located closer to the anodes 11R and 11B, the third light-emitting layer 13B_b may be located closer to the cathode 15, and the fourth light-emitting layer 13R_b may be located closer to the anodes 11R and 11B.

The light-emitting device 10G includes the first light-emitting layer 13G_a, the second light-emitting layer 13G_b, and the intermediate layer 21 between the anode 11G and the cathode 15. The intermediate layer 21 is preferably located between the first light-emitting layer 13G_a and the second light-emitting layer 13G_b. The light-emitting device 10G includes the first hole-injection/transport layer 12_a, the first electron-injection/transport layer 14_a, the second hole-injection/transport layer 12_b, and the second electron-injection/transport layer 14_b. The first hole-injection/transport layer 12_a is located between the anode 11B and the first light-emitting layer 13G_a. The first electron-injection/transport layer 14_a is located between the first light-emitting layer 13G_a and the intermediate layer 21. The second hole-injection/transport layer 12_b is located between the intermediate layer 21 and the second light-emitting layer 13G_b. The second electron-injection/transport layer 14_b is located between the second light-emitting layer 13G_b and the cathode 15.

The first light-emitting layer 13G_a and the second light-emitting layer 13G_b each include a light-emitting substance that emits light of a color different from the colors of light emitted by the first light-emitting layer 13B_a, the second light-emitting layer 13R_a, the third light-emitting layer 13B_b, and the fourth light-emitting layer 13R_b of the light-emitting devices 10R and 10B. The emission color of the light-emitting device 10G is different from the emission colors of the light-emitting devices 10R and 10B. Thus, in the display device 100, the emission color of the subpixel 50G can be different from the emission colors of the subpixel 50R and the subpixel 50B without a coloring layer.

For example, in the case where the first light-emitting layer 13B_a and the third light-emitting layer 13B_b of the light-emitting devices 10R and 10B include a blue-light-emitting substance and the second light-emitting layer 13R_a and the fourth light-emitting layer 13R_b of the light-emitting devices 10R and 10B include a red-light-emitting substance, the first light-emitting layer 13G_a and the second light-emitting layer 13G_b of the light-emitting device 10G preferably include a green-light-emitting substance. For another example, in the case where the first light-emitting layer 13B_a and the third light-emitting layer 13B_b of the light-emitting devices 10R and 10B include a green-light-emitting substance and the second light-emitting layer 13R_a and the fourth light-emitting layer 13R_b of the light-emitting devices 10R and 10B include a red-light-emitting substance, the first light-emitting layer 13G_a and the second light-emitting layer 13G_b of the light-emitting device 10G preferably include a blue-light-emitting substance. For another example, in the case where the first light-emitting layer 13B_a and the third light-emitting layer 13B_b of the light-emitting devices 10R and 10B include a blue-light-emitting substance and the second light-emitting layer 13R_a and the fourth light-emitting layer 13R_b of the light-emitting devices 10R and 10B include a green-light-emitting substance, the first light-emitting layer 13G_a and the second light-emitting layer 13G_b of the light-emitting device 10G preferably include a red-light-emitting substance.

In this specification and the like, a blue wavelength range is a wavelength range ranging from 400 nm to less than 490 nm, blue light emission is light emission whose emission spectrum has the maximum peak in this range, and a blue-light-emitting substance is a light-emitting substance whose emission spectrum has the maximum peak in this range. A green wavelength range is a wavelength range ranging from 490 nm to less than 580 nm, green light emission is light emission whose emission spectrum has the maximum peak in this range, and a green-light-emitting substance is a light-emitting substance whose emission spectrum has the maximum peak in this range. A red wavelength range is a wavelength range ranging from 580 nm to 750 nm, red light emission is light emission whose emission spectrum has the maximum peak in this range, and a red-light-emitting substance is a light-emitting substance whose emission spectrum has the maximum peak in this range.

The first light-emitting layer 13B_a, the second light-emitting layer 13R_a, the third light-emitting layer 13B_b, and the fourth light-emitting layer 13R_b of the light-emitting devices 10R and 10B and the first light-emitting layer 13G_a and the second light-emitting layer 13G_b of the light-emitting device 10G each preferably include one or more kinds of organic compounds (e.g., a host material) in addition to the light-emitting substance (guest material).

The intermediate layer 21 includes an organic compound and an alkali metal or an alkaline earth metal. As described above, the intermediate layer 21 is preferably a common layer. Thus, the intermediate layer 21 in the light-emitting device 10R, the intermediate layer 21 in the light-emitting device 10G, and the intermediate layer 21 in the light-emitting device 10B each preferably include an organic compound and an alkali metal or an alkaline earth metal, further preferably include the same organic compound and the same alkali metal or the same alkaline earth metal. Note that in this specification and the like, an intermediate layer is referred to as a charge-generation layer in some cases. The details of the intermediate layer (charge-generation layer) will be described later in Embodiment 3.

When the anodes 11R, 11B, and 11G are reflective electrodes and the cathode 15 is a transflective electrode to achieve a micro optical resonator (microcavity) structure in the light-emitting devices 10R, 10B, and 10G, light obtained from the light-emitting layers can be resonated between the electrodes to intensify light emitted from the cathode 15 side.

In the case where the anodes 11R, 11B, and 11G of the light-emitting devices 10R, 10B, and 10G are reflective electrodes having stacked-layer structures of reflective conductive materials 11R_a, 11B_a, and 11G_a and light-transmitting conductive materials (transparent conductive films) 11R_b, 11B_b, and 11G_b as illustrated in FIG. 2A, optical adjustment can be performed by adjusting the thicknesses of the transparent conductive films 11R_b, 11B_b, and 11G_b. Specifically, when the wavelength of light obtained from each light-emitting layer is 2, the optical path length between the anode 11R, 11B, or 11G and the cathode 15 (the product of the thickness and the refractive index) is preferably adjusted to be mλ/2 (m is an integer greater than or equal to 1) or close to mλ/2.

To amplify desired light (wavelength: 2) obtained from each light-emitting layer, it is preferable to adjust each of the optical path length from the anode 11R, 11B, or 11G to a region where the desired light is obtained in the light-emitting layer (light-emitting region) and the optical path length from the cathode 15 to the region where the desired light is obtained in the light-emitting layer (light-emitting region) to be (2m′+1)λ/4 (m′ is an integer greater than or equal to 1) or close to (2m′+1)λ/4. Here, the light-emitting region means a region where holes and electrons are recombined in the light-emitting layer.

By such optical adjustment, the spectrum of specific monochromatic light obtained from each light-emitting layer can be narrowed and light emission with high color purity can be obtained.

In the above case, the optical path length between the anode 11R, 11B, or 11G and the cathode 15 is, to be exact, the total thickness from a reflective region in the anode 11R, 11B, or 11G to a reflective region in the cathode 15. However, it is difficult to precisely determine the reflective regions in the anode 11R, 11B, or 11G and the cathode 15; thus, it is assumed that the above effect can be sufficiently obtained wherever the reflective regions may be set in the anode 11R, 11B, or 11G and the cathode 15. Furthermore, the optical path length between the anode 11R, 11B, or 11G and the light-emitting layer that emits the desired light is, to be exact, the optical path length between the reflective region in the anode 11R, 11B, or 11G and the light-emitting region in the light-emitting layer that emits the desired light. However, it is difficult to precisely determine the reflective region in the anode 11R, 11B, or 11G and the light-emitting region in the light-emitting layer that emits the desired light; thus, it is assumed that the above effect can be sufficiently obtained wherever the reflective region and the light-emitting region may be set in the anode 11R, 11B, or 11G and the light-emitting layer that emits the desired light, respectively. In the light-emitting devices 10R and 10B, the light-emitting region in the first light-emitting layer 13B_a and the second light-emitting layer 13R_a can be assumed to be in a position corresponding to the half of the total thickness of the first light-emitting layer 13B_a and the second light-emitting layer 13R_a, and the light-emitting region in the third light-emitting layer 13B_b and the fourth light-emitting layer 13R_b can be assumed to be in a position corresponding to the half of the total thickness of the third light-emitting layer 13B_b and the fourth light-emitting layer 13R_b. Note that in the case where the light-emitting devices 10R and 10B include a buffer layer between the first light-emitting layer 13B_a and the second light-emitting layer 13R_a and include a buffer layer between the third light-emitting layer 13B_b and the fourth light-emitting layer 13R_b, the light-emitting region in the first light-emitting layer 13B_a and the second light-emitting layer 13R_a can be assumed to be in a position corresponding to the half of the total thickness of the first light-emitting layer 13B_a, the buffer layer, and the second light-emitting layer 13R_a, and the light-emitting region in the third light-emitting layer 13B_b and the fourth light-emitting layer 13R_b can be assumed to be in a position corresponding to the half of the total thickness of the third light-emitting layer 13B_b, the buffer layer, and the fourth light-emitting layer 13R_b.

In the above light-emitting device of one embodiment of the present invention, at least one of the anode 11R, 11B, or 11G and the cathode 15 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ωcm.

When one of the anode 11R, 11B, or 11G and the cathode 15 is a reflective electrode in the above light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1× 10⁻² Ωcm.

Since the wavelengths in the red wavelength range (from 580 nm to 750 nm) are almost twice or specifically, greater than or equal to 1.18 times and less than or equal to 1.88 times the wavelengths in the blue wavelength range (from 400 nm to less than 490 nm), it is the most preferable that the first light-emitting layer 13B_a and the third light-emitting layer 13B_b include a blue-light-emitting substance and the second light-emitting layer 13R_a and the fourth light-emitting layer 13R_b include a red-light-emitting substance, in which case the light-emitting device 10R and the light-emitting device 10B can have a microcavity structure that intensifies both blue light emission and red light emission. This increases the emission efficiency of the light-emitting devices 10R and 10B and reduces the power consumption of the display device 100.

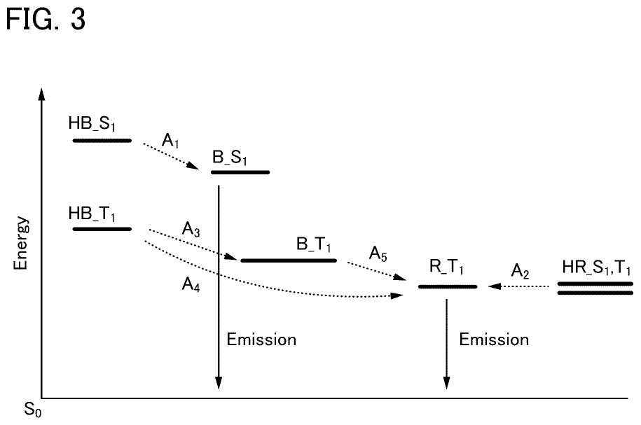

In the case where the first light-emitting layer 13B_a and the third light-emitting layer 13B_b include a blue-light-emitting substance and the second light-emitting layer 13R_a and the fourth light-emitting layer 13R_b include a red-light-emitting substance, the blue-light-emitting substance is preferably a fluorescent substance and the red-light-emitting substance is preferably a phosphorescent substance. In that case, it is preferable that the first light-emitting layer 13B_a and the third light-emitting layer 13B_b include a blue-light-emitting substance and a host material each having a higher T₁ level than the red-light-emitting substance included in the second light-emitting layer 13R_a and the fourth light-emitting layer 13R_b as illustrated in the energy diagram in FIG. 3. Note that in FIG. 3, the T₁ level and the S₁ level of the blue-light-emitting substance included in the first light-emitting layer 13B_a and the third light-emitting layer 13B_b are denoted as B_T₁ and B_S₁, respectively; the T₁ level and the S₁ level of the host material included in the first light-emitting layer 13B_a and the third light-emitting layer 13B_b are denoted as HB_T₁ and HB_S₁, respectively; the T₁ level of the red-light-emitting substance included in the second light-emitting layer 13R_a and the fourth light-emitting layer 13R_b is denoted as R_T₁; and the T₁ level and the S₁ level of the host material included in the second light-emitting layer 13R_a and the fourth light-emitting layer 13R_b are denoted as HR_S₁,T₁. Note that the host material included in the second light-emitting layer 13R_a and the fourth light-emitting layer 13R_b is an exciplex whose excited state is formed by two or more kinds of organic compounds, and has an S₁ level and a T₁ level close to each other.

Energy transfer in the stacked-layer structure of the first light-emitting layer 13B_a and the second light-emitting layer 13R_a or the stacked-layer structure of the third light-emitting layer 13B_b and the fourth light-emitting layer 13R_b is described with reference to FIG. 3. As illustrated in FIG. 3, in the first light-emitting layer 13B_a and the third light-emitting layer 13B_b, energy is transferred from the S₁ level (HB_S₁) of the host material to the S₁ level (B_S₁) of the blue-light-emitting substance by Route A₁, enabling the blue-light-emitting substance to emit light. In the second light-emitting layer 13R_a and the fourth light-emitting layer 13R_b, energy is transferred from the S₁ level and the T₁ level (HR_S₁,T₁) of the host material to the T₁ level (R_T₁) of the red-light-emitting substance by Route A₂, enabling the red-light-emitting substance to emit light. Furthermore, in the case where the T₁ level (B_T₁) of the blue-light-emitting substance included in the first light-emitting layer 13B_a and the third light-emitting layer 13B_b and the T₁ level (HB_T₁) of the host material included in the first light-emitting layer 13B_a and the third light-emitting layer 13B_b are higher than the T₁ level (R_T₁) of the red-light-emitting substance included in the second light-emitting layer 13R_a and the fourth light-emitting layer 13R_b as described above, the energy of the T₁ level of the host material can be transferred to the T₁ level (R_T₁) of the red-light-emitting substance by Routes A₃ and A₅ or Route A₄, enabling the red-light-emitting substance to emit light efficiently.

It is especially preferable that the first light-emitting layer 13B_a and the third light-emitting layer 13B_b include a blue-light-emitting substance, particularly a fluorescent substance, and the second light-emitting layer 13R_a and the fourth light-emitting layer 13R_b include a red-light-emitting substance, particularly a phosphorescent substance, as described above to significantly increase the emission efficiency of the light-emitting devices 10R and 10B.

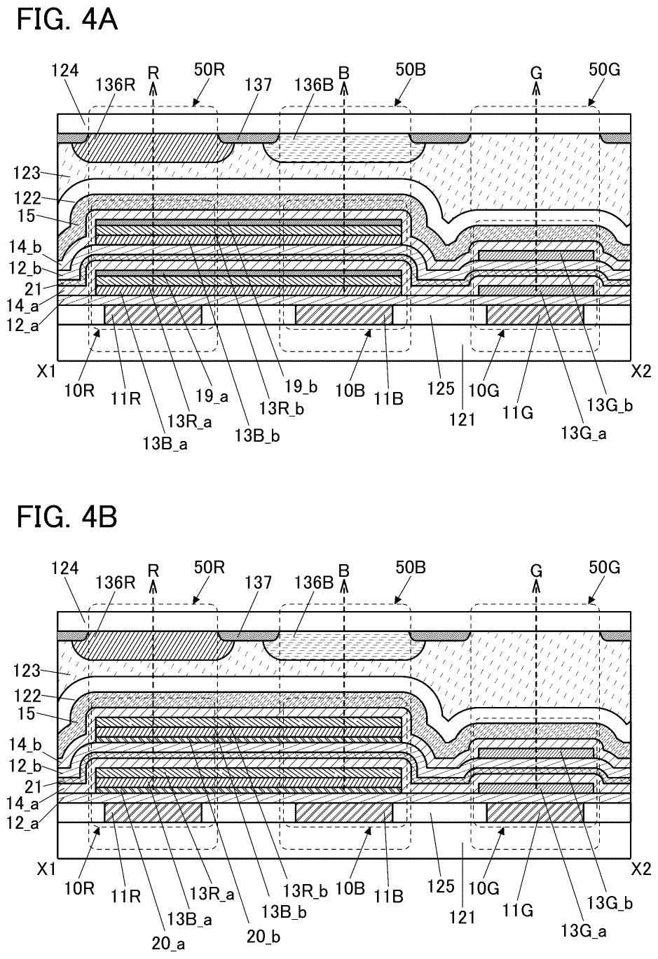

Next, variation examples of the display device 100 are described with reference to FIG. 2B, FIGS. 4A and 4B, FIGS. 5A and 5B, and FIGS. 6A and 6B.

The variation example illustrated in FIG. 2B is different from the display device 100 illustrated in FIG. 1B in that the thickness of the second light-emitting layer 13R_a is smaller than that of the first light-emitting layer 13B_a and the thickness of the fourth light-emitting layer 13R_b is smaller than that of the third light-emitting layer 13B_b. The other components are the same as those of the display device 100 illustrated in FIG. 1B; thus, description thereof is omitted here.

In a light-emitting device in which two light-emitting layers (a light-emitting layer L and a light-emitting layer S) having different emission colors are stacked to be in direct contact with each other as in the light-emitting devices 10R and 10B, the emission intensity of the light-emitting layer L emitting light with a long wavelength is sometimes higher than the emission intensity of the light-emitting layer S emitting light with a short wavelength (here, a peak wavelength of an emission spectrum of a light-emitting substance x included in the light-emitting layer L is longer than a peak wavelength of an emission spectrum of a light-emitting substance y included in the light-emitting layer S). This is partly because recombination energy is easily transferred to the light-emitting substance x, which has lower excitation energy and is more easily excited than the light-emitting substance y, in the case where the recombination region of the light-emitting device is in the vicinity of the interface between the light-emitting layer L and the light-emitting layer S, for example.

Thus, in the light-emitting devices 10R and 10B, the thickness of the light-emitting layer L, to which recombination energy is easily transferred, is preferably set to be smaller than the thickness of the light-emitting layer S to shift the carrier (hole and electron) recombination region to the light-emitting layer S. For example, in the case where the first light-emitting layer 13B_a and the third light-emitting layer 13B_b include a blue-light-emitting substance and the second light-emitting layer 13R_a and the fourth light-emitting layer 13R_b include a red-light-emitting substance in the light-emitting devices 10R and 10B, the thickness of the second light-emitting layer 13R_a is preferably smaller than that of the first light-emitting layer 13B_a, and the thickness of the fourth light-emitting layer 13R_b is preferably smaller than that of the third light-emitting layer 13B_b as in the variation example of the display device 100 illustrated in FIG. 2B. Such a structure enables shifting the recombination region to the light-emitting layer S, so that the emission intensity of the shorter-wavelength-light-emitting layer can be increased, and favorable light emission can be obtained from both the longer-wavelength-light-emitting layer and the shorter-wavelength-light-emitting layer.

Alternatively, in the light-emitting devices 10R and 10B, the recombination region is preferably shifted from the interface between the light-emitting layer L and the light-emitting layer S to the light-emitting layer S by enhancing the carrier-transport property of the light-emitting layer L. In the case of enhancing the carrier-transport property of a light-emitting layer closer to the anode among the light-emitting layers of the light-emitting device, the hole-transport property of the light-emitting layer is preferably enhanced. That is, the light-emitting layer preferably includes a hole-transport material, and further preferably has a higher hole-transport property than a light-emitting layer closer to the cathode. In the case of enhancing the carrier-transport property of the light-emitting layer closer to the cathode among the light-emitting layers, the electron-transport property of the light-emitting layer is preferably enhanced. That is, the light-emitting layer preferably includes an electron-transport material, and further preferably has a higher electron-transport property than the light-emitting layer closer to the anode. Structure examples of the hole-transport material and the electron-transport material will be described later in Embodiment 3. For example, in the case where the first light-emitting layer 13B_a and the third light-emitting layer 13B_b located closer to the anode include a light-emitting substance emitting short-wavelength blue light and the second light-emitting layer 13R_a and the fourth light-emitting layer 13R_b located closer to the cathode include a light-emitting substance emitting long-wavelength red light in the light-emitting devices 10R and 10B illustrated in FIG. 1B, the electron-transport properties of the second light-emitting layer 13R_a and the fourth light-emitting layer 13R_b are preferably higher than those of the first light-emitting layer 13B_a and the third light-emitting layer 13B_b. For example, it is preferable that the second light-emitting layer 13R_a and the fourth light-emitting layer 13R_b include an electron-transport material and that the first light-emitting layer 13B_a and the third light-emitting layer 13B_b include a hole-transport material. In that case, the recombination regions can be shifted to the first light-emitting layer 13B_a and the third light-emitting layer 13B_b, achieving favorable light emission from both the longer-wavelength-light-emitting layers and the shorter-wavelength-light-emitting layers. Meanwhile, in the case where the second light-emitting layer 13R_a and the fourth light-emitting layer 13R_b including a light-emitting substance emitting long-wavelength red light are located closer to the anode and the first light-emitting layer 13B_a and the third light-emitting layer 13B_b including a light-emitting substance emitting short-wavelength blue light are located closer to the cathode in the light-emitting devices 10R and 10B, the hole-transport properties of the second light-emitting layer 13R_a and the fourth light-emitting layer 13R_b are preferably higher than those of the first light-emitting layer 13B_a and the third light-emitting layer 13B_b. For example, it is preferable that the second light-emitting layer 13R_a and the fourth light-emitting layer 13R_b include a hole-transport material and that the first light-emitting layer 13B_a and the third light-emitting layer 13B_b include an electron-transport material. In that case, the recombination regions can be shifted to the first light-emitting layer 13B_a and the third light-emitting layer 13B_b, achieving favorable light emission from both the longer-wavelength-light-emitting layers and the shorter-wavelength-light-emitting layers.

The variation example illustrated in FIG. 4A is different from the display device 100 illustrated in FIG. 1B in that the light-emitting devices 10R and 10B include hole-blocking layers 19_a and 19_b. The other components are the same as those of the display device 100 illustrated in FIG. 1B; thus, description thereof is omitted here.

The hole-blocking layer 19_a illustrated in FIG. 4A can be formed using the same metal mask as the first light-emitting layer 13B_a and the second light-emitting layer 13R_a in the manufacturing process of the display device 100. The hole-blocking layer 19_b can be formed using the same metal mask as the third light-emitting layer 13B_b and the fourth light-emitting layer 13R_b in the manufacturing process of the display device 100. Thus, the hole-blocking layers 19_a and 19_b can be provided in the light-emitting devices 10R and 10B without complicating the manufacturing process. Providing the hole-blocking layers 19_a and 19_b sometimes enables controlling the carrier balance of the light-emitting devices 10R and 10B. Alternatively, providing the hole-blocking layers 19_a and 19_b sometimes facilitates optical adjustment of the light-emitting devices 10R and 10B. In that case, the hole-blocking layers 19_a and 19_b can be regarded as functioning as optical adjustment layers.

The variation example illustrated in FIG. 4B is different from the display device 100 illustrated in FIG. 1B in that the light-emitting devices 10R and 10B include electron-blocking layers 20_a and 20_b. The other components are the same as those of the display device 100 illustrated in FIG. 1B; thus, description thereof is omitted here.

The electron-blocking layer 20_a illustrated in FIG. 4B can be formed using the same metal mask as the first light-emitting layer 13B_a and the second light-emitting layer 13R_a in the manufacturing process of the display device 100. The electron-blocking layer 20_b can be formed using the same metal mask as the third light-emitting layer 13B_b and the fourth light-emitting layer 13R_b in the manufacturing process of the display device 100. Thus, the electron-blocking layers 20_a and 20_b can be provided in the light-emitting devices 10R and 10B without complicating the manufacturing process. Providing the electron-blocking layers 20_a and 20_b sometimes enables controlling the carrier balance of the light-emitting devices 10R and 10B. Alternatively, providing the electron-blocking layers 20_a and 20_b sometimes facilitates optical adjustment of the light-emitting devices 10R and 10B. In that case, the electron-blocking layers 20_a and 20_b can be regarded as functioning as optical adjustment layers.

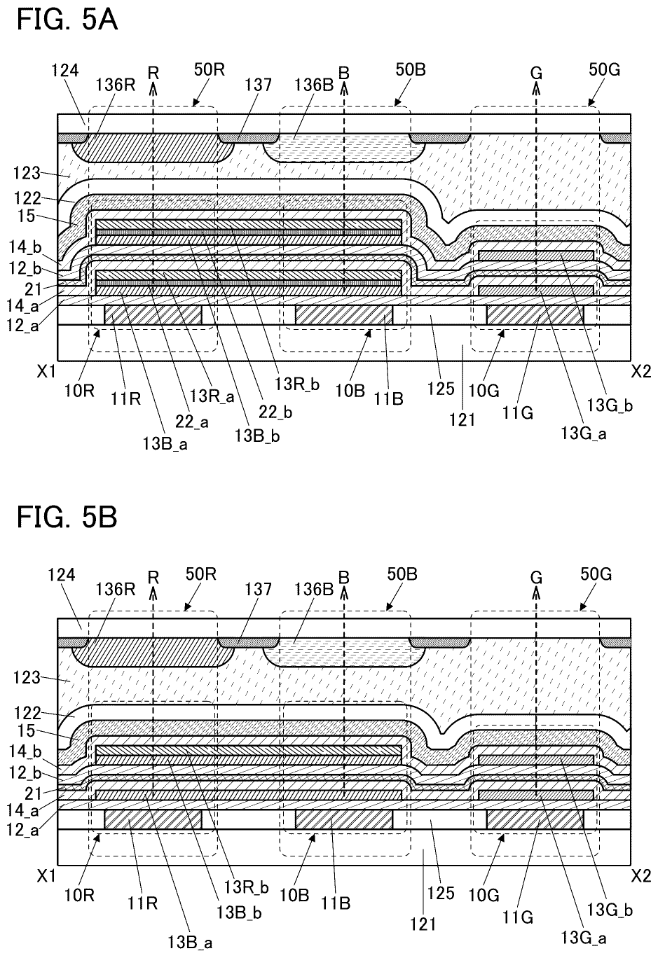

The variation example illustrated in FIG. 5A is different from the display device 100 illustrated in FIG. 1B in that the light-emitting devices 10R and 10B include buffer layers 22_a and 22_b. The other components are the same as those of the display device 100 illustrated in FIG. 1B; thus, description thereof is omitted here.

In FIG. 5A, the light-emitting devices 10R and 10B include the buffer layer 22_a between the first light-emitting layer 13B_a and the second light-emitting layer 13R_a and include the buffer layer 22_b between the third light-emitting layer 13B_b and the fourth light-emitting layer 13R_b. By providing the buffer layers between the light-emitting layers in this manner, the carrier balance is adjusted, enabling well-balanced emission of light with different wavelengths in the light-emitting devices 10R and 10B.

The buffer layers 22_a and 22_b can include, for example, an electron-transport material or a hole-transport material. Note that the buffer layers 22_a and 22_b having too large thicknesses might reduce the emission efficiency of the light-emitting devices 10R and 10B. In the case where the buffer layers 22_a and 22_b are provided, the buffer layers 22_a and 22_b each preferably have a thickness less than or equal to 5 nm to prevent a decrease in the emission efficiency of the light-emitting devices 10R and 10B and to enable well-balanced emission of light with different wavelengths.

The variation example illustrated in FIG. 5B is different from the display device 100 illustrated in FIG. 1B in that the light-emitting devices 10R and 10B do not include the second light-emitting layer 13R_a. The other components are the same as those of the display device 100 illustrated in FIG. 1B; thus, description thereof is omitted here.

For example, in the case where the fourth light-emitting layer 13R_b between the intermediate layer 21 and the cathode 15 is less likely to deteriorate than the third light-emitting layer 13B_b in the light-emitting devices 10R and 10B, the light-emitting devices 10R and 10B may have sufficiently high reliability even when only the first light-emitting layer 13B_a emitting light of the same color as the third light-emitting layer 13B_b is provided between the intermediate layer 21 and each of the anodes 11R and 11B as illustrated in FIG. 5B. For another example, in the case where the second light-emitting layer 13R_a between the intermediate layer 21 and each of the anodes 11R and 11B is less likely to deteriorate than the first light-emitting layer 13B_a in the light-emitting devices 10R and 10B, the light-emitting devices 10R and 10B may have sufficiently high reliability even when only the third light-emitting layer 13B_b emitting light of the same color as the first light-emitting layer 13B_a is provided between the intermediate layer 21 and the cathode 15.

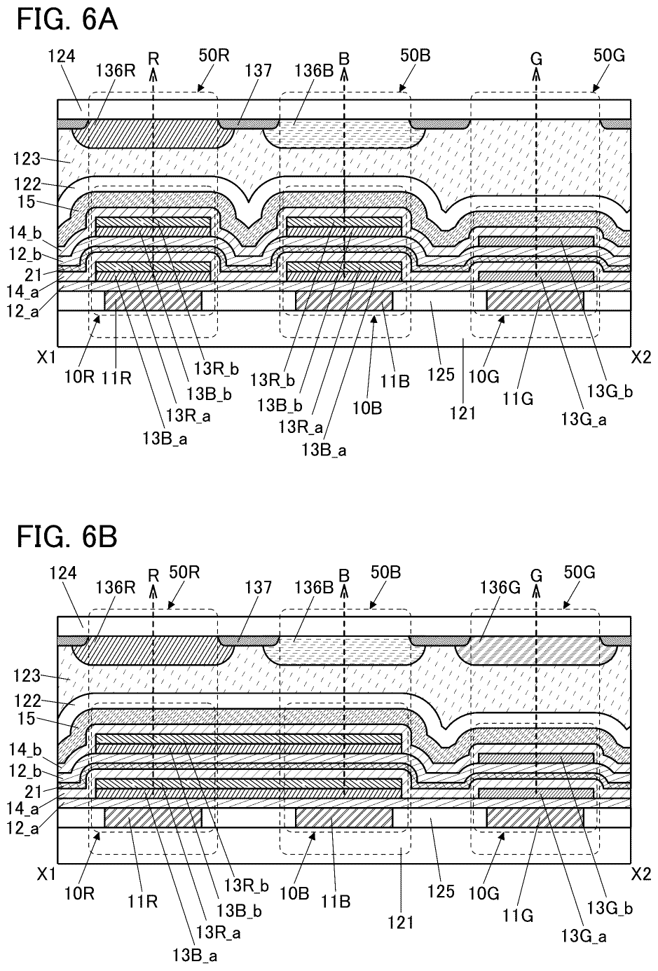

The variation example illustrated in FIG. 6A is different from the display device 100 illustrated in FIG. 1B in that the first light-emitting layer 13B_a, the second light-emitting layer 13R_a, the third light-emitting layer 13B_b, and the fourth light-emitting layer 13R_b of the light-emitting device 10R are separated from the first light-emitting layer 13B_a, the second light-emitting layer 13R_a, the third light-emitting layer 13B_b, and the fourth light-emitting layer 13R_b of the light-emitting device 10B. The other components are the same as those of the display device 100 illustrated in FIG. 1B; thus, description thereof is omitted here.

Even in the case where the first light-emitting layer 13B_a, the second light-emitting layer 13R_a, the third light-emitting layer 13B_b, and the fourth light-emitting layer 13R_b of the light-emitting device 10R are separated from the first light-emitting layer 13B_a, the second light-emitting layer 13R_a, the third light-emitting layer 13B_b, and the fourth light-emitting layer 13R_b of the light-emitting device 10B as described above, these layers can be formed in the same steps in the manufacturing process, and thus, the manufacturing process of the display device 100 can be simplified and the cost of the display device 100 can be reduced as in the case where the first light-emitting layer 13B_a, the second light-emitting layer 13R_a, the third light-emitting layer 13B_b, and the fourth light-emitting layer 13R_b are shared by the light-emitting devices 10R and 10B.

Since the first light-emitting layer 13B_a, the second light-emitting layer 13R_a, the third light-emitting layer 13B_b, and the fourth light-emitting layer 13R_b of the light-emitting device 10R can be separated from the first light-emitting layer 13B_a, the second light-emitting layer 13R_a, the third light-emitting layer 13B_b, and the fourth light-emitting layer 13R_b of the light-emitting device 10B as described above, the subpixel 50R and the subpixel 50B are not necessarily adjacent to each other in the pixel 110. This increases the structure flexibility of the pixel 110, which is preferable.

The variation example illustrated in FIG. 6B is different from the display device 100 illustrated in FIG. 1B in that the substrate 124 is provided with a coloring layer 136G that overlaps with the light-emitting device 10G. The other components are the same as those of the display device 100 illustrated in FIG. 1B; thus, description thereof is omitted here.

Providing the subpixel 50G with the light-emitting device 10G and the coloring layer 136G that overlaps with the light-emitting device 10G as illustrated in FIG. 6B makes it possible to adjust the chromaticity of the subpixel 50G, increasing the display quality of the display device 100.

The structures described in this embodiment can be used in appropriate combination with any of the structures described in the other embodiments.

### Embodiment 2

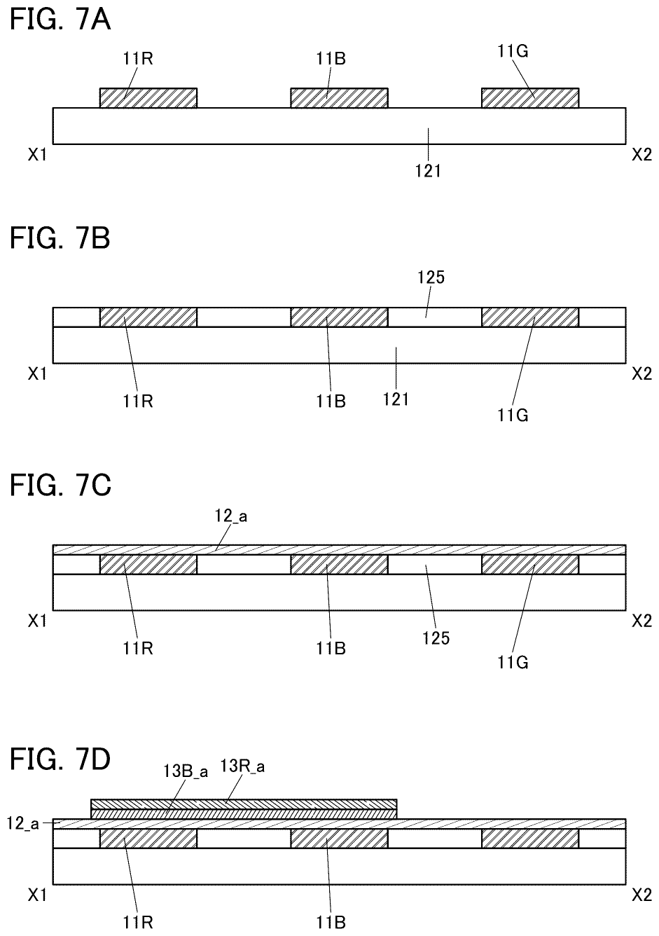

In this embodiment, a method for manufacturing the display device 100, which is a display device of one embodiment of the present invention, is described with reference to FIGS. 7A to 7D, FIGS. 8A to 8D, and FIGS. 9A to 9C, which are cross-sectional views of the display device 100 taken along the dashed-dotted line X1-X2 in FIG. 1A.

Note that thin films included in the display device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic CVD (MOCVD) method.

Alternatively, thin films included in the display device (e.g., insulating films, semiconductor films, and conductive films) can be formed by spin coating, dipping, spray coating, ink-jetting, dispensing, screen printing, or offset printing or with a doctor knife, a slit coater, a roll coater, a curtain coater, or a knife coater.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a light-emitting layer, an electron-transport layer, and an electron-injection layer) included in an EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

Thin films included in the display device can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Light exposure may be performed by liquid immersion exposure technique. As the light for exposure, extreme ultraviolet (EUV) light or X-rays may also be used. Furthermore, instead of the light for exposure, an electron beam can be used. EUV, X-rays, or an electron beam is preferably used to enable extremely minute processing. Note that a photomask is not needed when light exposure is performed by scanning with a beam such as an electron beam.

For etching of thin films, a dry etching method, a wet etching method, a sandblast method, or the like can be used.

First, over the layer 121 including transistors (not illustrated), the anodes 11R, 11G, and 11B are formed (see FIG. 7A). The anodes 11R, 11G, and 11B can be formed in the following manner: first, a conductive film such as a metal film is formed over the layer 121; a resist mask is then formed by a photolithography method; unnecessary portions of the conductive film are removed by etching; after that, the resist mask is removed.

Next, the insulating layer 125 is formed in a position being over the layer 121 and not overlapping with the anode 11R, 11G, or 11B (see FIG. 7B). Although not illustrated, part of the insulating layer 125 may overlap with end portions of the anodes 11R, 11G, and 11B.

Then, the first hole-injection/transport layer 12_a is formed over the anodes 11R, 11G, and 11B and the insulating layer 125 (see FIG. 7C).

Next, the first light-emitting layer 13B_a and the second light-emitting layer 13R_a are formed in a position being over the first hole-injection/transport layer 12_a and overlapping with the anodes 11R and 11B by a vacuum evaporation method using a metal mask (see FIG. 7D). Here, the first light-emitting layer 13B_a and the second light-emitting layer 13R_a can be successively formed using the same metal mask.

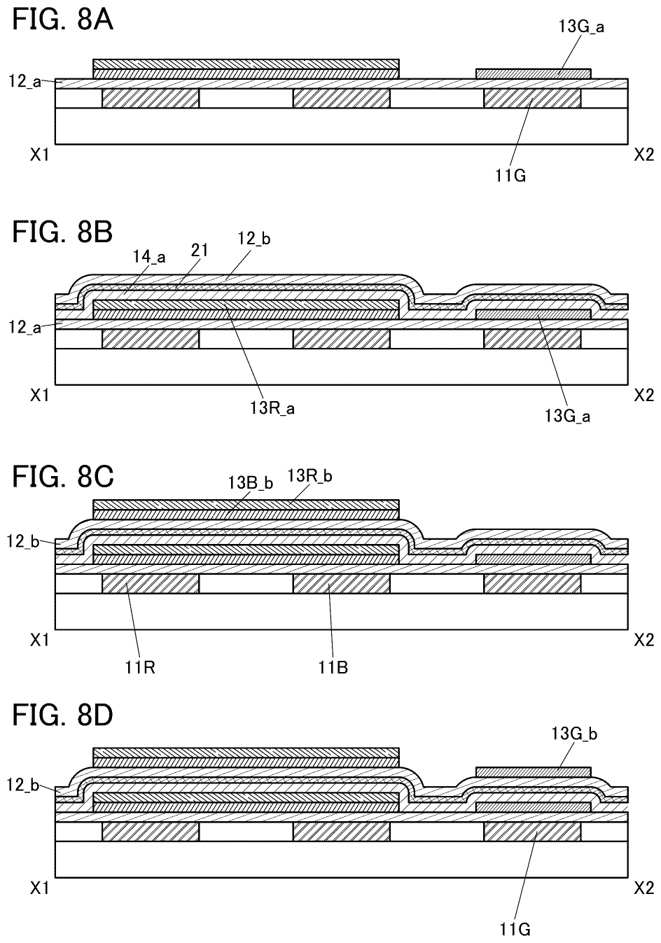

Furthermore, the first light-emitting layer 13G_a is formed in a position being over the first hole-injection/transport layer 12_a and overlapping with the anode 11G by a vacuum evaporation method using a metal mask (see FIG. 8A).

Then, the first electron-injection/transport layer 14_a, the intermediate layer 21, and the second hole-injection/transport layer 12_b are formed over the first hole-injection/transport layer 12_a and the second light-emitting layers 13R_a and 13G_a by a vacuum evaporation method (see FIG. 8B).

Next, the third light-emitting layer 13B_b and the fourth light-emitting layer 13R_b are formed in a position being over the second hole-injection/transport layer 12_b and overlapping with the anodes 11R and 11B by a vacuum evaporation method using a metal mask (see FIG. 8C). Here, the third light-emitting layer 13B_b and the fourth light-emitting layer 13R_b can be successively formed using the same metal mask.

Furthermore, the second light-emitting layer 13G_b is formed in a position being over the second hole-injection/transport layer 12_b and overlapping with the anode 11G by a vacuum evaporation method using a metal mask (see FIG. 8D).

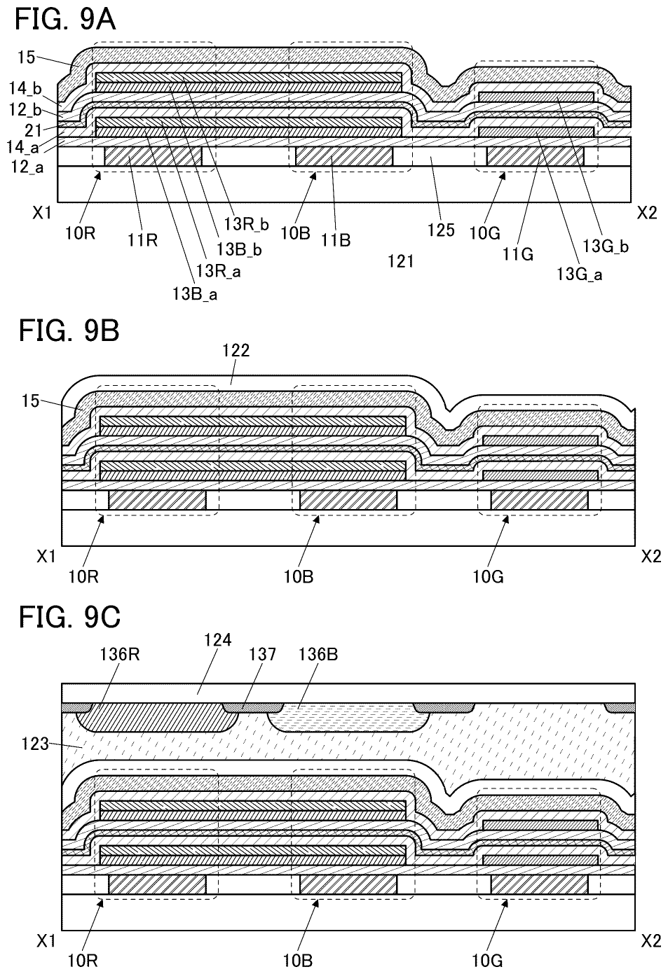

Next, the second electron-injection/transport layer 14_b is formed over the fourth light-emitting layer 13R_b and the second light-emitting layer 13G_b, and the cathode 15 is then formed over the second electron-injection/transport layer 14_b (FIG. 9A), whereby the light-emitting devices 10R, 10B, and 10G are provided. The cathode 15 can be formed by a sputtering method or a vacuum evaporation method, for example.

Then, the protective layer 122 is formed over the cathode 15 to cover the light-emitting devices 10R, 10B, and 10G (FIG. 9B).

Lastly, the substrate 124 provided with the coloring layers 136R and 136B and the black matrix 137 is attached using the resin layer 123, so that the display device of one embodiment of the present invention can be manufactured (FIG. 9C).

Since the tandem light-emitting devices are fabricated by the above-described method, the display device of one embodiment of the present invention is easy to manufacture as compared to the case where tandem light-emitting devices are fabricated by a three-color separate coloring method, and can be thus manufactured at lower cost.

The structures described in this embodiment can be used in appropriate combination with any of the structures described in the other embodiments.

### Embodiment 3

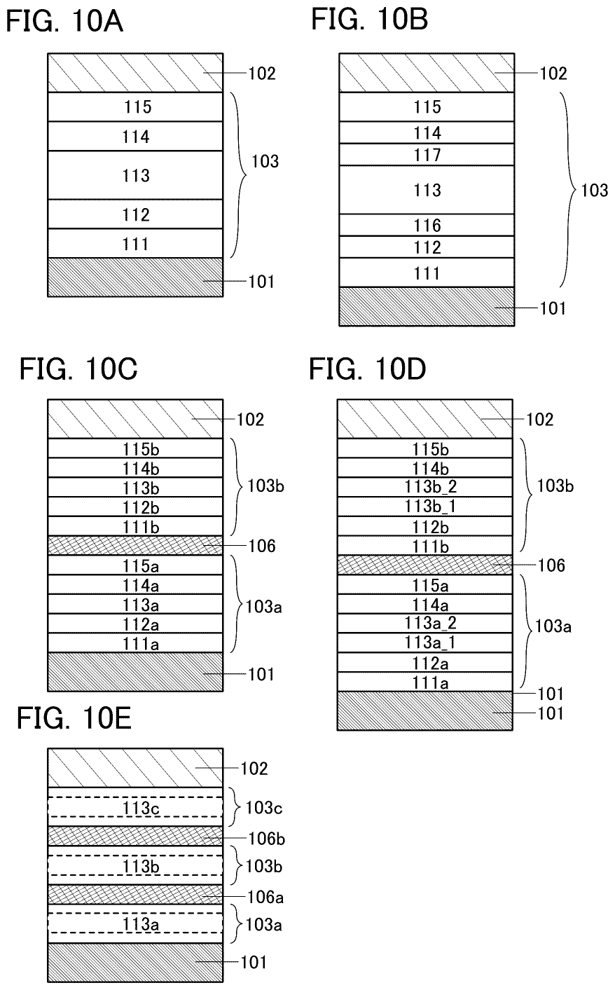

In this embodiment, structures of a light-emitting device that can be used in a display device of one embodiment of the present invention will be described with reference to FIGS. 10A to 10E.

### <<Basic Structure of Light-Emitting Device>>

A basic structure of a light-emitting device is described. FIG. 10A illustrates a light-emitting device including, between a pair of electrodes, an EL layer (also referred to as an organic compound layer) including a light-emitting layer. Specifically, an EL layer 103 is located between a first electrode 101 and a second electrode 102. In this case, the first electrode 101 is regarded as functioning as an anode, and the second electrode 102 is regarded as functioning as a cathode. The EL layer 103 has a structure in which a hole-injection layer 111, a hole-transport layer 112, a light-emitting layer 113, an electron-transport layer 114, and an electron-injection layer 115 are stacked in this order over the first electrode 101. As described in Embodiment 1, the stacked-layer structure of the hole-injection layer 111 and the hole-transport layer 112 may be collectively referred to as a hole-injection/transport layer. As described in Embodiment 1, the stacked-layer structure of the electron-transport layer 114 and the electron-injection layer 115 may be collectively referred to as an electron-injection/transport layer. The light-emitting layer 113 may have a structure in which a plurality of light-emitting layers having different emission colors are stacked to be in contact with each other as described in Embodiment 1. When the first electrode 101 is the cathode and the second electrode 102 is the anode, the stacking order of the layers in the EL layer 103 is reversed. Specifically, the layer 111 over the first electrode 101 serving as the cathode is an electron-injection layer; the layer 112 is an electron-transport layer; the layer 113 is a light-emitting layer; the layer 114 is a hole-transport layer; and the layer 115 is a hole-injection layer.

FIG. 10B illustrates a variation example of the stacked-layer structure illustrated in FIG. 10A. Also in this case, the first electrode 101 is regarded as functioning as an anode, and the second electrode 102 is regarded as functioning as a cathode. In this variation example, a hole-blocking layer and an electron-blocking layer are provided. That is, the EL layer 103 has a structure in which the hole-injection layer 111, the hole-transport layer 112, an electron-blocking layer 116, the light-emitting layer 113, a hole-blocking layer 117, the electron-transport layer 114, and the electron-injection layer 115 are stacked in this order over the first electrode 101. Note that the light-emitting layer 113 is located between the first electrode 101 and the second electrode 102. The light-emitting layer 113 may have a structure in which a plurality of light-emitting layers having different emission colors are stacked to be in contact with each other as described in Embodiment 1. The hole-transport layer 112 is located between the first electrode 101 and the light-emitting layer 113. The electron-transport layer 114 is located between the light-emitting layer 113 and the second electrode 102. The hole-injection layer 111 is located between the first electrode 101 and the hole-transport layer 112. The electron-injection layer 115 is located between the electron-transport layer 114 and the second electrode 102. The electron-blocking layer 116 is located between the hole-transport layer 112 and the light-emitting layer 113. In other words, the hole-blocking layer 117 is located between the light-emitting layer 113 and the electron-transport layer 114.

The electron-blocking layer 116 is provided to prevent passing of electrons from the light-emitting layer 113 to the first electrode 101 side, for example. The hole-blocking layer 117 is provided to prevent passing of holes from the light-emitting layer 113 to the second electrode 102 side, for example.

FIG. 10C illustrates a light-emitting device that has a stacked-layer structure (tandem structure) in which a plurality of EL layers (two EL layers 103a and 103b in FIG. 10C) are provided between a pair of electrodes and a charge-generation layer 106 is provided between the EL layers. A light-emitting device having a tandem structure enables manufacturing a light-emitting apparatus that has high efficiency without changing the amount of current.

The charge-generation layer 106 has a function of injecting electrons into one of the EL layers 103a and 103b and injecting holes into the other of the EL layers 103a and 103b when a potential difference is caused between the first electrode 101 and the second electrode 102. Thus, when voltage is applied such that the potential of the first electrode 101 is higher than that of the second electrode 102 in FIG. 10B, the charge-generation layer 106 injects electrons into the EL layer 103a and injects holes into the EL layer 103b.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

In the light-emitting device illustrated in FIG. 10C, the two EL layers (103a and 103b) include the respective light-emitting layers (113a and 113b), and the emission colors of the light-emitting layers can be selected freely. As the light-emitting device 10G described in Embodiment 1, a light-emitting device having the structure illustrated in FIG. 10C can be used, for example.

The light-emitting device illustrated in FIG. 10D is a variation example of the light-emitting device illustrated in FIG. 10C. The EL layer 103a includes a light-emitting layer 113a_1 and a light-emitting layer 113a_2 that are stacked to be in direct contact with each other, and the EL layer 103b includes a light-emitting layer 113b_1 and a light-emitting layer 113b_2 that are stacked to be in direct contact with each other. As each of the light-emitting devices 10R and 10B described in Embodiment 1, a light-emitting device having the structure illustrated in FIG. 10D can be used, for example.

The light-emitting device illustrated in FIG. 10E is an example of a light-emitting device having a tandem structure, and includes three EL layers (103a, 103b, and 103c) stacked with charge-generation layers (106a and 106b) located therebetween, as illustrated in FIG. 10E. The three EL layers (103a, 103b, and 103c) include the respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light, or the light-emitting layer 113a can emit red light, the light-emitting layer 113b can emit blue light, green light, or yellow light, and the light-emitting layer 113c can emit red light. The light-emitting layers (113a, 113b, and 113c) may each have a structure in which a plurality of light-emitting layers having different emission colors are stacked to be in contact with each other as described in Embodiment 1.

### <<Specific Structure of Light-Emitting Device>>

Next, a specific structure of the light-emitting device of one embodiment of the present invention will be described. Here, the description is made using FIG. 10C illustrating a tandem structure. Note that the structure of the EL layer applies also to the light-emitting devices having a single structure in FIGS. 10A and 10B.

### <First Electrode and Second Electrode>

As materials for the first electrode 101 and the second electrode 102, any of the following materials can be used in an appropriate combination as long as the above functions of the electrodes can be fulfilled. For example, a metal, an alloy, an electrically conductive compound, a mixture of these, and the like can be used as appropriate. Specifically, In—Sn oxide (also referred to as ITO), In—Si—Sn oxide (also referred to as ITSO), In—Zn oxide, or In—W—Zn oxide can be used. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table that is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

In the light-emitting device in FIG. 10C, when the first electrode 101 is the anode, a hole-injection layer 111a and a hole-transport layer 112a of the EL layer 103a are sequentially stacked over the first electrode 101 by a vacuum evaporation method. After the EL layer 103a and the charge-generation layer 106 are formed, a hole-injection layer 111b and a hole-transport layer 112b of the EL layer 103b are sequentially stacked over the charge-generation layer 106 in a similar manner.

### <Hole-Injection Layer>

The hole-injection layers (111, 111a, and 111b) inject holes from the first electrode 101 serving as the anode and the charge-generation layers (106, 106a, and 106b) to the EL layers (103, 103a, and 103b) and include an organic acceptor material and a material having a high hole-injection property.

The organic acceptor material allows holes to be generated in another organic compound whose HOMO level is close to the LUMO level of the organic acceptor material when charge separation is caused between the organic acceptor material and the organic compound. Thus, as the organic acceptor material, a compound having an electron-withdrawing group (e.g., a halogen group or a cyano group), such as a quinodimethane derivative, a chloranil derivative, or a hexaazatriphenylene derivative, can be used. For example, 7,7,8,8-tetracyano-2,3,5,6-tetrafluoroquinodimethane (abbreviation: F₄-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile can be used. Note that among organic acceptor materials, a compound in which electron-withdrawing groups are bonded to fused aromatic rings each having a plurality of heteroatoms, such as HAT-CN, is particularly preferable because it has a high acceptor property and stable film quality against heat. Besides, a [3]radialene derivative having an electron-withdrawing group (particularly a cyano group or a halogen group such as a fluoro group), which has a very high electron-accepting property, is preferable; specifically, it is possible to use α,α′,α″-1,2,3-cyclopropanetriylidenetris[4-cyano-2,3,5,6-tetrafluorobenzeneacetonitrile], α,α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like.

As the material having a high hole-injection property, an oxide of a metal belonging to Group 4 to Group 8 of the periodic table (e.g., a transition metal oxide such as molybdenum oxide, vanadium oxide, ruthenium oxide, tungsten oxide, or manganese oxide) can be used. Specific examples include molybdenum oxide, vanadium oxide, niobium oxide, tantalum oxide, chromium oxide, tungsten oxide, manganese oxide, and rhenium oxide. Among the above oxides, molybdenum oxide is preferable because it is stable in the air, has a low hygroscopic property, and is easy to handle. Other examples include a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F₆), 3,4,9,10-perylenetetracarboxylic diimide (abbreviation: PTCDI), or 3,4,9,10-perylenetetracarboxyl-bis-benzimidazole (abbreviation: PTCBI); (C₆₀—Iₕ)[5,6]fullerene (abbreviation: C₆₀); (C₇₀-D₅ₕ)[5,6]fullerene (abbreviation: C₇₀); an organic compound such as phthalocyanine (abbreviation: H₂Pc); and a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). A phthalocyanine-based metal complex such as CuPc or ZnPc and 2,3,8,9,14,15-hexafluorodiquinoxalino[2,3-a:2′,3′-c]phenazine are especially preferable. Among these materials, CuPc and ZnPc are preferable because they are inexpensive and have favorable characteristics. Using ZnPc, which has a low diffusion coefficient with respect to silicon, reduces the probability that metal diffusion to a semiconductor adversely affects the semiconductor characteristics; accordingly, ZnPc is particularly suitable for a display device manufactured using a silicon semiconductor.

Other examples include aromatic amine compounds, which are low-molecular compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), and poly[N,N′-bis(4-butylphenyl)-N,N′-bis(phenyl)benzidine](abbreviation: Poly-TPD). Alternatively, it is possible to use a high-molecular compound to which acid is added, such as poly(3,4-ethylenedioxythiophene)/polystyrenesulfonic acid (abbreviation: PEDOT/PSS) or polyaniline/polystyrenesulfonic acid (abbreviation: PAni/PSS), for example.

As the material having a high hole-injection property, a mixed material containing a hole-transport material and the above-described organic acceptor material (electron-accepting material) can be used. In that case, the organic acceptor material extracts electrons from the hole-transport material, so that holes are generated in the hole-injection layer and the holes are injected into the light-emitting layer through the hole-transport layer. Note that the hole-injection layer may be formed to have a single-layer structure using a mixed material containing a hole-transport material and an organic acceptor material (electron-accepting material), or a stacked-layer structure of a layer including a hole-transport material and a layer including an organic acceptor material (electron-accepting material).

The hole-transport material is preferably a substance having a hole mobility higher than or equal to 1×10⁻⁶ cm²/Vs in the case where the square root of the electric field strength [V/cm]is 600. Note that other substances can also be used as long as the substances have hole-transport properties higher than electron-transport properties.

Preferable examples of the hole-transport material include hole-transport materials such as a compound having a π-electron rich heteroaromatic ring (e.g., a carbazole derivative, a furan derivative, and a thiophene derivative) and an aromatic amine (an organic compound having an aromatic amine skeleton).

Examples of the carbazole derivative (an organic compound having a carbazole ring) include a bicarbazole derivative (e.g., a 3,3′-bicarbazole derivative) and an aromatic amine having a carbazolyl group.

Specific examples of the bicarbazole derivative (e.g., a 3,3′-bicarbazole derivative) include 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), and 9-(2-naphthyl)-9′-phenyl-3,3′-bi-9H-bicarbazole (abbreviation: QNCCP).

Specific examples of the aromatic amine having a carbazolyl group include 4-phenyl-4′-(9-phenyl-9H-carbazol-3-yl)triphenylamine (abbreviation: PCBA1BP), N-(biphenyl-4-yl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-(1,1′:3′,1″-terphenyl-4-yl)-9,9-dimethyl-9H-fluoren-2-amine, N-[4-(9-phenyl-9H-carbazol-3-yl)phenyl]-N-(1,1′:4′,1″-terphenyl-4-yl)-9,9-dimethyl-9H-fluoren-2-amine, N-[4-(9-phenyl-9H-carbazol-3-yl)phenyl]-N-(1,1′:3′,1″-terphenyl-4-yl)-9,9-dimethyl-9H-fluoren-4-amine, N-[4-(9-phenyl-9H-carbazol-3-yl)phenyl]-N-(1,1′:4′,1″-terphenyl-4-yl)-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N′-bis(9-phenylcarbazol-3-yl)-N,N′-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), N-(9,9-spirobi[9H-fluoren]-2-yl)-N,9-diphenylcarbazol-3-amine (abbreviation: PCASF), N-(4-biphenyl)-4-(carbazol-9-yl)phenylaniline (abbreviation: YGA1BP), N,N-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

Other examples of the carbazole derivative include 9-[4-(9-phenyl-9H-carbazol-3-yl)phenyl]phenanthrene (abbreviation: PCPPn), 3-[4-(1-naphthyl)phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the furan derivative (an organic compound having a furan ring) include 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II).

Specific examples of the thiophene derivative (an organic compound having a thiophene ring) include organic compounds having a thiophene ring such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Specific examples of the aromatic amine include 4,4′-bis[N-(1-naphthyl)-N-phenylamino]biphenyl (abbreviation: NPB or α-NPD), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), N-(9,9-spirobi[9H-fluoren]-2-yl)-N,N′,N″-triphenyl-1,4-phenyldiamine (abbreviation: DPASF), N,N′-diphenyl-N,N′-bis(4-diphenylaminophenyl)spirobi[9H-fluorene]-2,7-diamine (abbreviation: DPA2SF), 4,4′,4″-tris[N-(1-naphthyl)-N-phenylamino]triphenylamine (abbreviation: 1′-TNATA), 4,4′,4″-tris(N,N′-diphenylamino)triphenylamine (abbreviation: TDATA), 4,4′,4″-tris[N-(3-methylphenyl)-N-phenylamino]triphenylamine (abbreviation: m-MTDATA), N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), DNTPD, 1,3,5-tris[N-(4-diphenylaminophenyl)-N-phenylamino]benzene (abbreviation: DPA3B), N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)-triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Other examples of the hole-transport material include high-molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide](abbreviation: PTPDMA), and poly[N,N′-bis(4-butylphenyl)-N,N′-bis(phenyl)benzidine](abbreviation: Poly-TPD). Alternatively, it is possible to use a high-molecular compound to which acid is added, such as poly(3,4-ethylenedioxythiophene)/polystyrenesulfonic acid (abbreviation: PEDOT/PSS) or polyaniline/polystyrenesulfonic acid (abbreviation: PAni/PSS), for example.

Note that the hole-transport material is not limited to the above examples, and any of a variety of known materials may be used alone or in combination as the hole-transport material.

The hole-injection layers (111, 111a, and 111b) can be formed by any of known film formation methods such as a vacuum evaporation method.

### <Hole-Transport Layer>

The hole-transport layers (112, 112a, and 112b) transport the holes, which are injected from the first electrodes 101 by the hole-injection layers (111, 111a, and 1l1b), to the light-emitting layers (113, 113a, 113b, and 113c). Note that the hole-transport layers (112, 112a, and 112b) each include a hole-transport material. Thus, the hole-transport layers (112, 112a, and 112b) can be formed using any of the hole-transport materials that can be used for the hole-injection layers (111, 111a, and 111b).

Note that in the light-emitting device of one embodiment of the present invention, the organic compound used for the hole-transport layers (112, 112a, and 112b) can also be used for the light-emitting layers (113, 113a, 113b, and 113c). The same organic compound is preferably used for the hole-transport layers (112, 112a, and 112b) and the light-emitting layers (113, 113a, 113b, and 113c), in which case holes can be efficiently transported from the hole-transport layers (112, 112a, and 112b) to the light-emitting layers (113, 113a, 113b, and 113c).

### <Electron-Blocking Layer>

The electron-blocking layer 116 is provided to prevent passing of electrons from the light-emitting layer 113 to the first electrode 101 side. A material having an excellent hole-transport property, a low electron-transport property, and a high LUMO level is suitable for the electron-blocking layer 116. The electron-blocking layer 116 is preferably formed using any of the substances which are given as examples of the material usable for the hole-transport layer 112 and whose LUMO level is higher (preferably more than or equal to 0.30 eV higher) than that of a material (at least a host material) included in the light-emitting layer. Note that the electron-blocking layer, which transports holes, can also be regarded as part of the hole-transport layer 112.

### <Light-Emitting Layer>

The light-emitting layers (113, 113a, 113b, and 113c) include a light-emitting substance. Note that as a light-emitting substance that can be used in the light-emitting layers (113, 113a, 113b, and 113c), a substance whose emission color is blue, violet, bluish violet, green, yellowish green, yellow, orange, red, or the like can be used as appropriate. When a plurality of light-emitting layers are provided, the use of different light-emitting substances for the light-emitting layers enables exhibiting different emission colors (e.g., white light emission obtained by a combination of complementary emission colors). When a plurality of light-emitting layers are provided, the light-emitting layers can exhibit the same color. The structure in which a plurality of light-emitting layers that emit light of the same color are stacked can sometimes achieve higher reliability than a single-layer structure. Furthermore, one light-emitting layer may have a stacked-layer structure including different light-emitting substances.

The light-emitting layers (113, 113a, 113b, and 113c) may each include one or more kinds of organic compounds (e.g., a host material) in addition to a light-emitting substance (a guest material).

In the case where a plurality of host materials are used in the light-emitting layers (113, 113a, 113b, and 113c), a second host material that is additionally used is preferably a substance having a larger energy gap than those of the guest material and a first host material included in the light-emitting layers. Preferably, the lowest singlet excitation energy level (S₁ level) of the second host material is higher than that of the first host material, and the lowest triplet excitation energy level (T₁ level) of the second host material is higher than that of the guest material. Preferably, the lowest triplet excitation energy level (T₁ level) of the second host material is higher than that of the first host material. With such a structure, an exciplex can be formed by the two kinds of host materials. To form an exciplex efficiently, it is particularly preferable to combine a compound that easily accepts holes (hole-transport material) and a compound that easily accepts electrons (electron-transport material). With the above structure, high efficiency, low voltage, and a long lifetime can be achieved at the same time.

As an organic compound used as the host material (including the first host material and the second host material), any of organic compounds such as the hole-transport materials usable for the hole-transport layers (112, 112a, and 112b) described above and electron-transport materials usable for electron-transport layers (114, 114a, and 114b) described later can be used as long as they satisfy requirements for the host material used in the light-emitting layer. Another example is an exciplex formed by two or more kinds of organic compounds (the first host material and the second host material). An exciplex whose excited state is formed by two or more kinds of organic compounds has an extremely small difference between the S₁ level and the T₁ level and functions as a thermally activated delayed fluorescent (TADF) material capable of converting triplet excitation energy into singlet excitation energy. In an example of a preferable combination of two or more kinds of organic compounds forming an exciplex, one compound of the two or more kinds of organic compounds has a π-electron deficient heteroaromatic ring and the other compound has a π-electron rich heteroaromatic ring. A phosphorescent substance such as an iridium-, rhodium-, or platinum-based organometallic complex or a metal complex may be used as one compound of the combination for forming an exciplex.

There is no particular limitation on the light-emitting substances that can be used for the light-emitting layers (113, 113a, 113b, and 113c), and a light-emitting substance that converts singlet excitation energy into light in the visible light range or a light-emitting substance that converts triplet excitation energy into light in the visible light range can be used.

<<Light-Emitting Substance that Converts Singlet Excitation Energy into Light>>The following substances that emit fluorescent light (fluorescent substances) can be given as examples of the light-emitting substance that converts singlet excitation energy into light and that can be used in the light-emitting layers (113, 113a, 113b, and 113c): a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-diphenyl-N,N′-bis[4-(9-phenyl-9H-fluoren-9-yl)phenyl]pyrene-1,6-diamine (abbreviation: 1,6FLPAPrn), N,N′-bis(dibenzofuran-2-yl)-N,N′-diphenylpyrene-1,6-diamine (abbreviation: 1,6FrAPrn), N,N′-bis(dibenzothiophen-2-yl)-N,N′-diphenylpyrene-1,6-diamine (abbreviation: 1,6ThAPrn), N,N′-(pyrene-1,6-diyl)bis[(N-phenylbenzo[b]naphtho[1,2-d]furan)-6-amine](abbreviation: 1,6BnfAPrn), N,N′-(pyrene-1,6-diyl)bis[(N-phenylbenzo[b]naphtho[1,2-d]furan)-8-amine](abbreviation: 1,6BnfAPrn-02), and N,N′-(pyrene-1,6-diyl)bis[(6,N-diphenylbenzo[b]naphtho[1,2-d]furan)-8-amine](abbreviation: 1,6BnfAPrn-03).

In addition, it is possible to use, for example, 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-bis[4-(9H-carbazol-9-yl)phenyl]-N,N′-diphenyl-4,4′-stilbenediamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra-tert-butylperylene (abbreviation: TBP), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), or N-[4-(9,10-diphenyl-2-anthryl)phenyl]-N,N′,N′-triphenyl-1,4-phenylenediamine (abbreviation: 2DPAPPA).

It is also possible to use, for example, N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, NN-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), 1,6BnfAPrn-03, N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), or 3,10-bis[N-(dibenzofuran-3-yl)-N-phenylamino]naphtho[2,3-b;6,7-b′]bisbenzofuran (abbreviation: 3,10FrA2Nbf(IV)-02). In particular, a pyrenediamine compound such as 1,6FLPAPrn, 1,6mMemFLPAPrn, or 1,6BnfAPrn-03 can be used, for example.

<<Light-Emitting Substance that Converts Triplet Excitation Energy into Light>>

Examples of the light-emitting substance that converts triplet excitation energy into light and that can be used in the light-emitting layer 113 include substances that emit phosphorescent light (phosphorescent substances) and TADF materials that exhibit thermally activated delayed fluorescence.

A phosphorescent substance is a compound that emits phosphorescent light but does not emit fluorescent light at a temperature higher than or equal to a low temperature (e.g., 77 K) and lower than or equal to room temperature (i.e., higher than or equal to 77 K and lower than or equal to 313 K). The phosphorescent substance preferably contains a metal element with large spin-orbit interaction, and can be an organometallic complex, a metal complex (platinum complex), or a rare earth metal complex, for example. Specifically, the phosphorescent substance preferably contains a transition metal element as the metal element with large spin-orbit interaction. It is preferable that the phosphorescent substance contain a platinum group element (ruthenium (Ru), rhodium (Rh), palladium (Pd), osmium (Os), iridium (Ir), or platinum (Pt)), especially iridium, in which case the probability of direct transition between the singlet ground state and the triplet excited state can be increased.

<<Phosphorescent substance (from 400 nm to less than 580 nm: blue or green)>>

As examples of a phosphorescent substance which emits blue or green light and whose emission spectrum has a peak wavelength greater than or equal to 400 nm and less than 580 nm, the following substances can be given.

Examples include organometallic complexes having a 4H-triazole ring, such as tris{2-[5-(2-methylphenyl)-4-(2,6-dimethylphenyl)-4H-1,2,4-triazol-3-yl-κN²]phenyl-κC}iridium(III) (abbreviation: [Jr(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), and tris[3-(5-biphenyl)-5-isopropyl-4-phenyl-4H-1,2,4-triazolato]iridium(III) (abbreviation: [Jr(iPr5btz)₃]); organometallic complexes having a 1H-triazole ring, such as tris[3-methyl-1-(2-methylphenyl)-5-phenyl-1H-1,2,4-triazolato]iridium(III) (abbreviation: [Jr(Mptz1-mp)₃]) and tris(1-methyl-5-phenyl-3-propyl-1H-1,2,4-triazolato)iridium(III) (abbreviation: [Jr(Prptz1-Me)₃]); organometallic complexes having an imidazole ring, such as fac-tris[1-(2,6-diisopropylphenyl)-2-phenyl-1H-imidazole]iridium(III) (abbreviation: [Ir(iPrpim)₃]) and tris[3-(2,6-dimethylphenyl)-7-methylimidazo[1,2-f]phenanthridinato]iridium(III) (abbreviation: [Jr(dmpimpt-Me)₃]); and organometallic complexes in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)).

<<Phosphorescent Substance (from 490 nm to Less than 590 nm: Green or Yellow)>>

As examples of a phosphorescent substance which emits green or yellow light and whose emission spectrum has a peak wavelength greater than or equal to 490 nm and less than 590 nm, the following substances can be given.

Examples of the phosphorescent substance include organometallic iridium complexes having a pyrimidine ring, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine ring, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine ring, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), bis[2-(2-pyridinyl-κN)phenyl-κC][2-(4-phenyl-2-pyridinyl-κN)phenyl-κC]iridium(III) (abbreviation: [Ir(ppy)₂(4dppy)]), bis[2-(2-pyridinyl-κN)phenyl-κC][2-(4-methyl-5-phenyl-2-pyridinyl-κN)phenyl-κC], [2-d₃-methyl-8-(2-pyridinyl-N)benzofuro[2,3-b]pyridine-κC]bis[2-(5-d₃-methyl-2-pyridinyl-κN²)phenyl-κC]iridium(III) (abbreviation: Ir(5mppy-d3)₂(mbfpypy-d3)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d3)), and [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); organometallic complexes such as bis(2,4-diphenyl-1,3-oxazolato-N,C^{2′})iridium(III) acetylacetonate (abbreviation: [Ir(dpo)₂(acac)]), bis{2-[4′-(perfluorophenyl)phenyl]pyridinato-N,C^{2′}}iridium(III) acetylacetonate (abbreviation: [Ir(p-PF-ph)₂(acac)]), and bis(2-phenylbenzothiazolato-N,C^{2′})iridium(III) acetylacetonate (abbreviation: [Ir(bt)₂(acac)]); and a rare earth metal complex such as tris(acetylacetonato)(monophenanthroline)terbium(III) (abbreviation: [Tb(acac)₃(Phen)]).

<<Phosphorescent Substance (from 570 nm to Less than 750 nm: Yellow or Red)>>

As examples of a phosphorescent substance which emits yellow or red light and whose emission spectrum has a peak wavelength greater than or equal to 570 nm and less than 750 nm, the following substances can be given.

Examples of the phosphorescent substance include organometallic complexes having a pyrimidine ring, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and (dipivaloylmethanato)bis[4,6-di(naphthalen-1-yl)pyrimidinato]iridium(III) (abbreviation: [Ir(d1npm)₂(dpm)]); organometallic complexes having a pyrazine ring, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-xN]phenyl-κC}(2,6-dimethyl-3,5-heptanedionato-κ²O,O′)iridium(III) (abbreviation: [Ir(dmdppr-P)₂(dibm)]), bis{4,6-dimethyl-2-[5-(4-cyano-2,6-dimethylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), bis{2-[5-(2,6-dimethylphenyl)-3-(3,5-dimethylphenyl)-2-pyrazinyl-κN]-4,6-dimethylphenyl-xC}(2,2′,6,6′-tetramethyl-3,5-heptanedionato-κ²O,O′)iridium(III) (abbreviation: [Ir(dmdppr-dmp)₂(dpm)]), (acetylacetonato)bis(2-methyl-3-phenylquinoxalinato-N,C^{2′})iridium(III) (abbreviation: [Ir(mpq)₂(acac)]), (acetylacetonato)bis(2,3-diphenylquinoxalinato-N,C^{2′})iridium(III) (abbreviation: [Ir(dpq)₂(acac)]), and (acetylacetonato)bis[2,3-bis(4-fluorophenyl)quinoxalinato]iridium(III) (abbreviation: [Ir(Fdpq)₂(acac)]); organometallic complexes having a pyridine ring, such as tris(1-phenylisoquinolinato-N,C^{2′})iridium(III) (abbreviation: [Ir(piq)₃]), bis(1-phenylisoquinolinato-N,C²′)iridium(III) acetylacetonate (abbreviation: [Ir(piq)₂(acac)]), and bis[4,6-dimethyl-2-(2-quinolinyl-κN)phenyl-κC](2,4-pentanedionato-κ2O,O′)iridium(III) (abbreviation: [Ir(dmpqn)₂(acac)]); a platinum complex such as 2,3,7,8,12,13,17,18-octaethyl-21H,23H-porphyrin platinum(II) (abbreviation: [PtOEP]); and rare earth metal complexes such as tris(1,3-diphenyl-1,3-propanedionato)(monophenanthroline)europium(III) (abbreviation: [Eu(DBM)₃(Phen)]) and tris[l-(2-thenoyl)-3,3,3-trifluoroacetonato](monophenanthroline)europium(III) (abbreviation: [Eu(TTA)₃(Phen)]).

### <<TADF Material>>

Any of materials described below can be used as the TADF material. The TADF material is a material that has a small difference between its S₁ and T₁ levels (preferably less than or equal to 0.20 eV), enables up-conversion of a triplet excited state into a singlet excited state (i.e., reverse intersystem crossing) using a little thermal energy, and efficiently exhibits light (fluorescent light) from the singlet excited state. The thermally activated delayed fluorescence is efficiently obtained under the condition where the difference in energy between the triplet excitation energy level and the singlet excitation energy level is greater than or equal to 0.00 eV and less than or equal to 0.20 eV, preferably greater than or equal to 0.00 eV and less than or equal to 0.10 eV. Delayed fluorescent light by the TADF material refers to light emission having a spectrum similar to that of normal fluorescent light and an extremely long lifetime. The lifetime is longer than or equal to 1×10⁻⁶ seconds, or longer than or equal to 1×10⁻³ seconds.

Note that the TADF material can be also used as an electron-transport material, a hole-transport material, or a host material.

Examples of the TADF material include fullerene, a derivative thereof, an acridine derivative such as proflavine, and eosin. Other examples thereof include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

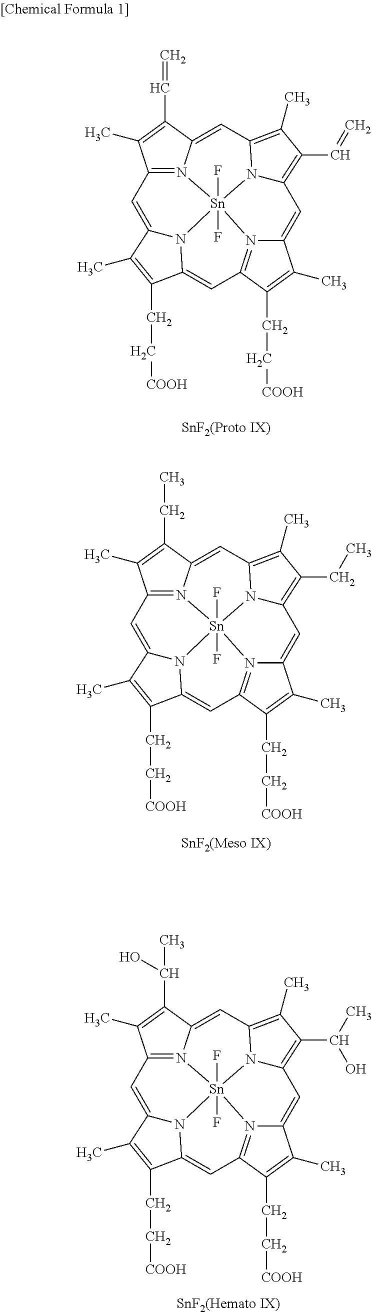

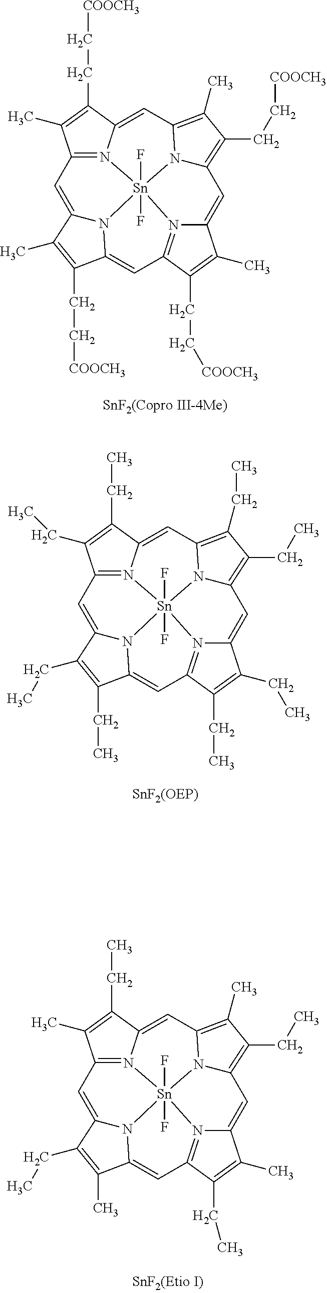

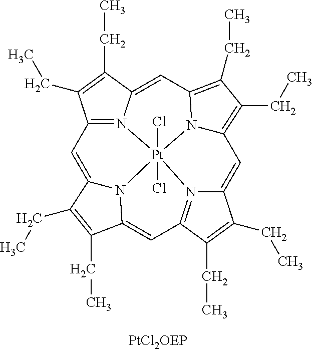

Additionally, a heteroaromatic compound having a π-electron rich heteroaromatic compound and a π-electron deficient heteroaromatic compound, such as 2-(biphenyl-4-yl)-4,6-bis(12-phenylindolo[2,3-a]carbazol-11-yl)-1,3,5-triazine (abbreviation: PIC-TRZ), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbazol-9-yl)benzofuro[3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), or 9-[3-(4,6-diphenyl-1,3,5-triazin-2-yl)phenyl]-9′-phenyl-2,3′-bi-9H-carbazole (abbreviation: mPCCzPTzn-02) may be used.

Note that a substance in which a π-electron rich heteroaromatic compound is directly bonded to a π-electron deficient heteroaromatic compound is particularly preferable because both the donor property of the π-electron rich heteroaromatic compound and the acceptor property of the π-electron deficient heteroaromatic compound are enhanced and the energy difference between the singlet excited state and the triplet excited state becomes small. As the TADF material, a TADF material in which the singlet and triplet excited states are in thermal equilibrium (TADF100) may be used. Since such a TADF material enables a short emission lifetime (excitation lifetime), the efficiency of a light-emitting device in a high-luminance region can be less likely to decrease.

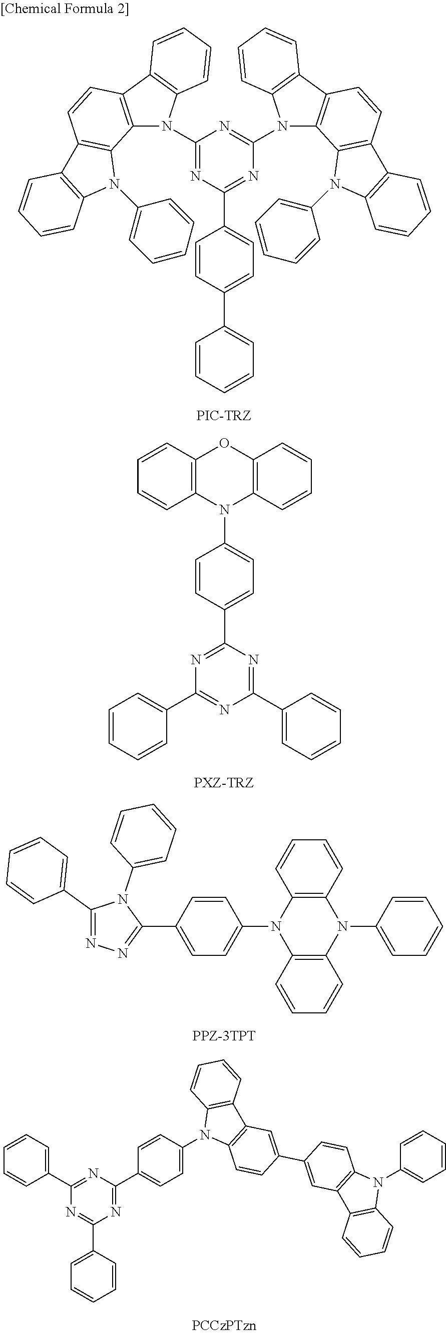 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

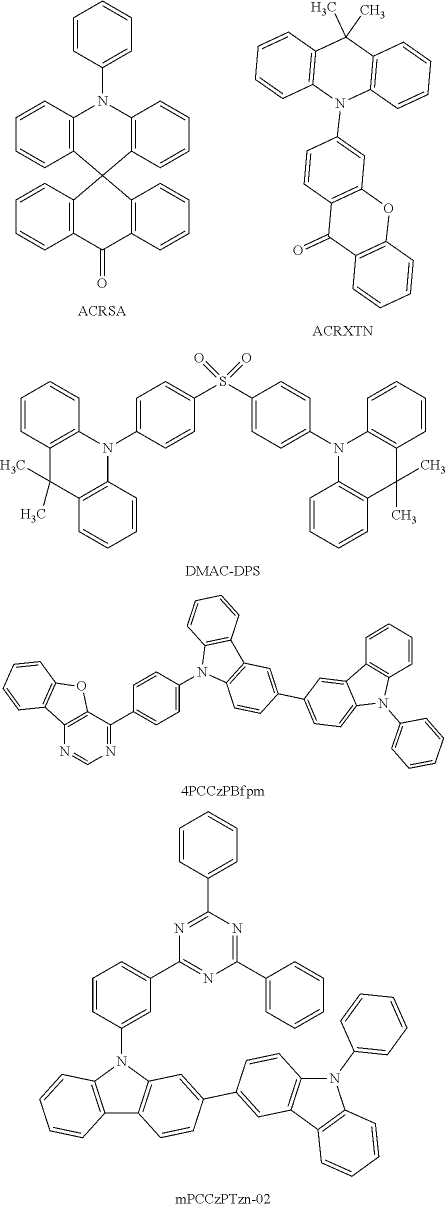 [SMILES: O=C1c2ccccc2C2(c3ccccc31)c1ccccc1N(c1ccccc1)c1ccccc12 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; c1ccc(-n2c3ccccc3c3cc(-c4ccc5c(c4)c4ccccc4n5-c4ccc(-c5ncnc6c5oc5ccccc56)cc4)ccc32)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

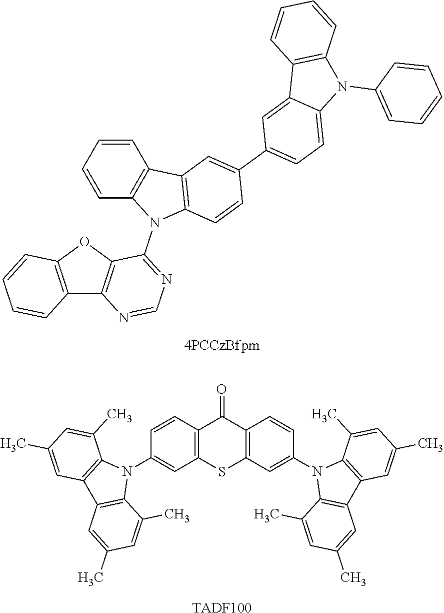

In addition to the above, another example of a material having a function of converting triplet excitation energy into light is a nano-structure of a transition metal compound having a perovskite structure. In particular, a nano-structure of a metal halide perovskite material is preferable. The nano-structure is preferably a nanoparticle or a nanorod.

As the organic compound (e.g., the host material) used in combination with the above-described light-emitting substance (guest material) in the light-emitting layers (113, 113a, 113b, and 113c), one or more selected from substances having a larger energy gap than the light-emitting substance (guest material) can be used.

### <<Host Material for Fluorescence>>

In the case where the light-emitting substance used in the light-emitting layers (113, 113a, 113b, and 113c) is a fluorescent substance, an organic compound (host material) used in combination with the fluorescent substance is preferably an organic compound that has a high energy level in a singlet excited state and has a low energy level in a triplet excited state or an organic compound having a high fluorescence quantum yield. Thus, the hole-transport material (described above) and the electron-transport material (described below) shown in this embodiment, for example, can be used as long as they are organic compounds that satisfy such a condition.

In terms of a preferable combination with the light-emitting substance (fluorescent substance), examples of the organic compound (host material), some of which overlap the above specific examples, include fused polycyclic aromatic compounds such as an anthracene derivative, a tetracene derivative, a phenanthrene derivative, a pyrene derivative, a chrysene derivative, and a dibenzo[g,p]chrysene derivative.

Specific examples of the organic compound (host material) that is preferably used in combination with the fluorescent substance include 9-phenyl-3-[4-(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), 3-[4-(1-naphthyl)phenyl]-9-phenyl-9H-carbazole (abbreviation: PCPN), 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N,N,N′,N′,N″,N″-octaphenyldibenzo[g,p]chrysene-2,7,10,15-tetraamine (abbreviation: DBC1), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9-(1-naphthyl)-10-(2-naphthyl)anthracene (abbreviation: α,β-ADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(1-naphthyl)-10-[4-(2-naphthyl)phenyl]anthracene (abbreviation: αN-βNPAnth), 2,9-di(1-naphthyl)-10-phenylanthracene (abbreviation: 2α,N-αNPhA), 9-(1-naphthyl)-10-[3-(1-naphthyl)phenyl]anthracene (abbreviation: α,N-mαNPAnth), 9-(2-naphthyl)-10-[3-(1-naphthyl)phenyl]anthracene (abbreviation: βN-mαNPAnth), 9-(1-naphthyl)-10-[4-(1-naphthyl)phenyl]anthracene (abbreviation: α,N-αNPAnth), 9-(2-naphthyl)-10-[4-(2-naphthyl)phenyl]anthracene (abbreviation: βN-βNPAnth), 2-(1-naphthyl)-9-(2-naphthyl)-10-phenylanthracene (abbreviation: 2αN-βNPhA), 9-(2-naphthyl)-10-[3-(2-naphthyl)phenyl]anthracene (abbreviation: βN-mβNPAnth), 1-{4-[10-(biphenyl-4-yl)-9-anthracenyl]phenyl}-2-ethyl-1H-benzimidazole (abbreviation: EtBImPBPhA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), 5,12-diphenyltetracene, and 5,12-bis(biphenyl-2-yl)tetracene.

### <<Host Material for Phosphorescence>>

In the case where the light-emitting substance used in the light-emitting layers (113, 113a, 113b, and 113c) is a phosphorescent substance, an organic compound having triplet excitation energy (an energy difference between a ground state and a triplet excited state) which is higher than that of the light-emitting substance may be selected as the organic compound (host material) used in combination with the phosphorescent substance. Note that when a plurality of organic compounds (e.g., a first host material and a second host material (or an assist material)) are used in combination with a light-emitting substance to form an exciplex, the plurality of organic compounds are preferably mixed with the phosphorescent substance.

With such a structure, light emission can be efficiently obtained by exciplex-triplet energy transfer (ExTET), which is energy transfer from an exciplex to a light-emitting substance. Note that a combination of the plurality of organic compounds that easily forms an exciplex is preferable, and it is particularly preferable to combine a compound that easily accepts holes (hole-transport material) and a compound that easily accepts electrons (electron-transport material).

In terms of a preferable combination with the light-emitting substance (phosphorescent substance), examples of the organic compounds (the host material and the assist material), some of which overlap the above specific examples, include an aromatic amine (an organic compound having an aromatic amine skeleton), a carbazole derivative (an organic compound having a carbazole ring), a dibenzothiophene derivative (an organic compound having a dibenzothiophene ring), a dibenzofuran derivative (an organic compound having a dibenzofuran ring), an oxadiazole derivative (an organic compound having an oxadiazole ring), a triazole derivative (an organic compound having an triazole ring), a benzimidazole derivative (an organic compound having an benzimidazole ring), a quinoxaline derivative (an organic compound having a quinoxaline ring), a dibenzoquinoxaline derivative (an organic compound having a dibenzoquinoxaline ring), a pyrimidine derivative (an organic compound having a pyrimidine ring), a triazine derivative (an organic compound having a triazine ring), a pyridine derivative (an organic compound having a pyridine ring), a bipyridine derivative (an organic compound having a bipyridine ring), a phenanthroline derivative (an organic compound having a phenanthroline ring), a furodiazine derivative (an organic compound having a furodiazine ring), and zinc- or aluminum-based metal complexes.

Among the above organic compounds, specific examples of the aromatic amine and the carbazole derivative, which are organic compounds having a high hole-transport property, are the same as the specific examples of the hole-transport materials described above, and those materials are preferable as the host material.

Among the above organic compounds, specific examples of the dibenzothiophene derivative and the dibenzofuran derivative, which are organic compounds having a high hole-transport property, include 4-{3-[3-(9-phenyl-9H-fluoren-9-yl)phenyl]phenyl}dibenzofuran (abbreviation: mmDBFFLBi-II), 4,4′,4″-(benzene-1,3,5-triyl)tri(dibenzofuran) (abbreviation: DBF3P-II), DBT3P-II, 2,8-diphenyl-4-[4-(9-phenyl-9H-fluoren-9-yl)phenyl]dibenzothiophene (abbreviation: DBTFLP-III), 4-[4-(9-phenyl-9H-fluoren-9-yl)phenyl]-6-phenyldibenzothiophene (abbreviation: DBTFLP-IV), and 4-[3-(triphenylen-2-yl)phenyl]dibenzothiophene (abbreviation: mDBTPTp-II). These derivatives are preferable as the host material.

Other examples of preferable host materials include metal complexes having an oxazole-based or thiazole-based ligand, such as bis[2-(2-benzoxazolyl)phenolato]zinc(II) (abbreviation: ZnPBO) and bis[2-(2-benzothiazolyl)phenolato]zinc(II) (abbreviation: ZnBTZ).

Among the above organic compounds, specific examples of the oxadiazole derivative, the triazole derivative, the benzimidazole derivative, the quinoxaline derivative, the dibenzoquinoxaline derivative, the quinazoline derivative, and the phenanthroline derivative, which are organic compounds having a high electron-transport property, include an organic compound including a heteroaromatic ring having a polyazole ring such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: COl1), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound including a heteroaromatic ring having a phenanthroline ring such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), or 2,2′-(1,3-phenylene)bis(9-phenyl-1,10-phenanthroline) (abbreviation: mPPhen2P); and an organic compound including a heteroaromatic ring having a dibenzoquinoxaline ring such as 2-[3-(dibenzothiophen-4-yl)phenyl]dibenzo[f;h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 2-{4-[9,10-di(2-naphthyl)-2-anthryl]phenyl}-1-phenyl-1H-benzimidazole (abbreviation: ZADN), or 2-[4′-(9-phenyl-9H-carbazol-3-yl)-3,1′-biphenyl-1-yl]dibenzo[f,h]quinoxaline (abbreviation: 2mpPCBPDBq). These organic compounds are preferable as the host material.

Among the above organic compounds, specific examples of the pyridine derivative, the diazine derivative (e.g., the pyrimidine derivative, the pyrazine derivative, and the pyridazine derivative), the triazine derivative, and the furodiazine derivative, which are organic compounds having a high electron-transport property, include organic compounds including a heteroaromatic ring having a diazine ring such as 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 9,9′-[pyrimidine-4,6-diylbis(biphenyl-3,3′-diyl)]bis(9H-carbazole) (abbreviation: 4,6mCzBP2Pm), 2-[3′-(9,9-dimethyl-9H-fluoren-2-yl)biphenyl-3-yl]-4,6-diphenyl-1,3,5-triazine (abbreviation: mFBPTzn), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 11-[3′-(dibenzothiophen-4-yl)biphenyl-3-yl]phenanthro[9′,10′:4,5]furo[2,3-b]pyrazine (abbreviation: 11mDBtBPPnfpr), 11-[3′-(dibenzothiophen-4-yl)biphenyl-4-yl]phenanthro[9′,10′:4,5]furo[2,3-b]pyrazine, 11-[3′-(9H-carbazol-9-yl)biphenyl-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[3′-(9-phenyl-9H-carbazol-3-yl)biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9H-carbazol-9-yl)naphtho[1′,2′:4,5]furo[2,3-b]pyrazine (abbreviation: 10PCCzNfpr), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl)biphenyl-3-yl]naphtho[1′,2′:4,5]furo[2,3-b]pyrazine (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-[3′-(2,8-diphenyldibenzothiophen-4-yl)biphenyl-3-yl]naphtho[1′,2′:4,5]furo[2,3-b]pyrazine, 11-[3′-(2,8-diphenyldibenzothiophen-4-yl)biphenyl-3-yl]phenanthro[9′,10′:4,5]furo[2,3-b]pyrazine, 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 6-(biphenyl-3-yl)-4-[3,5-bis(9H-carbazol-9-yl)phenyl)-2-phenylpyrimidine (abbreviation: 6mBP-4Cz2PPm), and 4-[3,5-bis(9H-carbazol-9-yl)phenyl]-2-phenyl-6-(biphenyl-4-yl)pyrimidine (abbreviation: 6BP-4Cz2PPm), and these materials are preferable as the host material.

Among the above organic compounds, specific examples of metal complexes that are organic compounds having a high electron-transport property include zinc- or aluminum-based metal complexes, such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), and bis(8-quinolinolato)zinc(II) (abbreviation: Znq), and metal complexes having a quinoline ring or a benzoquinoline ring. These metal complexes are preferable as the host material.

Moreover, high-molecular compounds such as poly(2,5-pyridinediyl) (abbreviation: PPy), poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)](abbreviation: PF-BPy) are preferable as the host material.

Furthermore, the following organic compounds with a diazine ring, which have a bipolar property, a high hole-transport property, and a high electron-transport property, can be used as the host material: 9-phenyl-9′-(4-phenyl-2-quinazolinyl)-3,3′-bi-9H-carbazole (abbreviation: PCCzQz), 2-[4′-(9-phenyl-9H-carbazol-3-yl)-3,1′-biphenyl-1-yl]dibenzo[f,h]quinoxaline (abbreviation: 2mpPCBPDBq), 5-[3-(4,6-diphenyl-1,3,5-triazin-2-yl)phenyl]-7,7-dimethyl-5H,7H-indeno[2,1-b]carbazole (abbreviation: mINc(II)PTzn), 11-[4-(biphenyl-4-yl)-6-phenyl-1,3,5-triazin-2-yl]-11,12-dihydro-12-phenyl-indolo[2,3-a]carbazole (abbreviation: BP-Icz(II)Tzn), and 7-[4-(9-phenyl-9H-carbazol-2-yl)quinazolin-2-yl]-7H-dibenzo[c,g]carbazole (abbreviation: PC-cgDBCzQz).

### <Hole-Blocking Layer>

The hole-blocking layer 117 is provided to prevent passing of holes from the light-emitting layer 113 to the second electrode 102 side. A material having an excellent electron-transport property, a low hole-transport property, and a deep HOMO level is suitable for the hole-blocking layer 117. The hole-blocking layer 117 is preferably formed using any of substances which will be given as examples of the material usable for the electron-transport layer 114 and whose HOMO level is lower (preferably more than or equal to 0.30 eV lower) than that of a material (at least a host material) included in the light-emitting layer. Note that the hole-blocking layer, which transports electrons, can also be regarded as part of the electron-transport layer 114.

### <Electron-Transport Layer>

The electron-transport layers (114, 114a, and 114b) transport the electrons, which are injected from the second electrode 102 and the charge-generation layers (106, 106a, and 106b) by the electron-injection layers (115, 115a, and 115b) described later, to the light-emitting layers (113, 113a, 113b, and 113c). The heat resistance of the light-emitting device of one embodiment of the present invention can be improved by including the stacked electron-transport layers. The electron-transport material used in the electron-transport layers (114, 114a, and 114b) is preferably a substance having an electron mobility higher than or equal to 1×10⁻⁶ cm²/Vs in the case where the square root of the electric field strength [V/cm] is 600. Note that any other substance can also be used as long as the substance has an electron-transport property higher than a hole-transport property. The electron-transport layers (114, 114a, and 114b) can function even with a single-layer structure and may have a stacked-layer structure including two or more layers.

### <<Electron-Transport Material>>

As the electron-transport material that can be used for the electron-transport layers (114, 114a, and 114b), an organic compound having a high electron-transport property can be used, and for example, a heteroaromatic compound can be used. The term heteroaromatic compound refers to a cyclic compound including at least two different kinds of elements in a ring. Examples of cyclic structures include a three-membered ring, a four-membered ring, a five-membered ring, a six-membered ring, and the like, among which a five-membered ring and a six-membered ring are particularly preferable. The elements included in the heteroaromatic compound are preferably one or more of nitrogen, oxygen, sulfur, and the like in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a π-electron deficient heteroaromatic compound including the nitrogen-containing heteroaromatic compound, is preferably used.

Note that the electron-transport material can be different from the materials used in the light-emitting layer. Not all excitons formed by recombination of carriers in the light-emitting layer can contribute to light emission and some excitons are diffused into a layer in contact with the light-emitting layer or a layer in the vicinity of the light-emitting layer. In order to avoid this phenomenon, the energy level (the lowest singlet excitation level or the lowest triplet excitation level) of a material used for the layer in contact with the light-emitting layer or the layer in the vicinity of the light-emitting layer is preferably higher than that of a material used for the light-emitting layer. Thus, when a material different from the material of the light-emitting layer is used as the electron-transport material, a device having high efficiency can be obtained.

The heteroaromatic compound is an organic compound including at least one heteroaromatic ring.

The heteroaromatic ring includes any one of a pyridine ring, a diazine ring, a triazine ring, a polyazole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having a polyazole ring includes a heteroaromatic ring having an imidazole ring, a triazole ring, or an oxadiazole ring.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of the heteroaromatic compound having a five-membered ring structure, which is a heteroaromatic compound containing carbon and one or more of nitrogen, oxygen, sulfur, and the like, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of the heteroaromatic compound having a six-membered ring structure, which is a heteroaromatic compound containing carbon and one or more of nitrogen, oxygen, sulfur, and the like include a heteroaromatic compound having a heteroaromatic ring, such as a pyridine ring, a diazine ring (a pyrimidine ring, a pyrazine ring, a pyridazine ring, or the like), a triazine ring, or a polyazole ring. Other examples include a heteroaromatic compound having a bipyridine structure, a heteroaromatic compound having a terpyridine structure, and the like, which are included in examples of a heteroaromatic compound in which pyridine rings are connected.

Examples of the heteroaromatic compound having a fused ring structure partly including the above six-membered ring structure include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to a furan ring of a furodiazine ring), or a benzimidazole ring.

Specific examples of the above-described heteroaromatic compound having a five-membered ring structure (a polyazole ring (including an imidazole ring, a triazole ring, or an oxadiazole ring), an oxazole ring, a thiazole ring, or a benzimidazole ring) include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOs).

Specific examples of the above-described heteroaromatic compound having a six-membered ring structure (including a heteroaromatic ring having a pyridine ring, a diazine ring, a triazine ring, or the like) include a heteroaromatic compound including a heteroaromatic ring having a pyridine ring, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); a heteroaromatic compound including a heteroaromatic ring having a triazine ring, such as 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-{3-[3-(dibenzothiophen-4-yl)phenyl]phenyl}-4,6-diphenyl-1,3,5-triazine (abbreviation: mDBtBPTzn), or mFBPTzn; and a heteroaromatic compound including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 4,6mCzBP2Pm, 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), 4-[3-(dibenzothiophen-4-yl)phenyl]-8-(naphthalen-2-yl)-[1]benzofuro[3,2-d]pyrimidine (abbreviation: 8βN-4mDBtPBfpm), 8BP-4mDBtPBfpm, 9mDBtBPNfpr, 9pmDBtBPNfpr, 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), or 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm). Note that examples of the above aromatic compounds including a heteroaromatic ring include a heteroaromatic compound having a fused heteroaromatic ring.

Other examples include heteroaromatic compounds including a heteroaromatic ring having a diazine (pyrimidine) ring, such as 2,2′-(pyridine-2,6-diyl)bis(4-phenylbenzo[h]quinazoline) (abbreviation: 2,6(P-Bqn)2Py), 2,2′-(2,2′-bipyridine-6,6′-diyl)bis(4-phenylbenzo[h]quinazoline) (abbreviation: 6,6′(P-Bqn)2BPy), 2,2′-(pyridine-2,6-diyl)bis{4-[4-(2-naphthyl)phenyl]-6-phenylpyrimidine}(abbreviation: 2,6(NP—PPm)2Py), or 6-(biphenyl-3-yl)-4-[3,5-bis(9H-carbazol-9-yl)phenyl]-2-phenylpyrimidine (abbreviation: 6mBP-4Cz2PPm), and a heteroaromatic compound including a heteroaromatic ring having a triazine ring, such as 2,4,6-tris(3′-(pyridin-3-yl)biphenyl-3-yl)-1,3,5-triazine (abbreviation: TmPPPyTz), 2,4,6-tris(2-pyridyl)-1,3,5-triazine (abbreviation: 2Py3Tzn), or 2-[3-(2,6-dimethyl-3-pyridyl)-5-(9-phenanthryl)phenyl]-4,6-diphenyl-1,3,5-triazine (abbreviation: mPn-mDMePyPTzn).

Specific examples of the above-described heteroaromatic compound having a fused ring structure partly including a six-membered ring structure (the heteroaromatic compound having a fused ring structure) include a heteroaromatic compound having a quinoxaline ring, such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2,2′-(pyridin-2,6-diyl)bis(4-phenylbenzo[h]quinazoline) (abbreviation: 2,6(P-Bqn)2Py), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), and 2mpPCBPDBq.

For the electron-transport layers (114, 114a, and 114b), any of the metal complexes given below can be used as well as the heteroaromatic compounds described above. Examples of the metal complexes include a metal complex having a quinoline ring or a benzoquinoline ring, such as tris(8-quinolinolato)aluminum(III) (abbreviation: Alq₃), Almq₃, 8-quinolinolato-lithium (abbreviation: Liq), BeBq₂, bis(2-methyl-8-quinolinolato)(4-phenylphenolato)aluminum(III) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO) or bis[2-(2-benzothiazolyl)phenolato]zinc(II) (abbreviation: ZnBTZ).

High-molecular compounds such as poly(2,5-pyridinediyl) (abbreviation: PPy), poly[(9,9-dihexylfluorene-2,7-diyl)-co-(pyridine-3,5-diyl)](abbreviation: PF-Py), and poly[(9,9-dioctylfluorene-2,7-diyl)-co-(2,2′-bipyridine-6,6′-diyl)](abbreviation: PF-BPy) can be used as the electron-transport material.

Each of the electron-transport layers (114, 114a, and 114b) is not limited to a single layer and may be a stack of two or more layers each including any of the above substances.

### <Electron-Injection Layer>

The electron-injection layers (115, 115a, and 115b) include a substance having a high electron-injection property. The electron-injection layers (115, 115a, and 115b) are layers for increasing the efficiency of electron injection from the second electrode 102 and are preferably formed using a material whose value of the LUMO level has a small difference (less than or equal to 0.50 eV) from the work function of a material used for the second electrode 102. Thus, the electron-injection layer 115 can be formed using an alkali metal, an alkaline earth metal, or a compound thereof, such as lithium, cesium, lithium fluoride (LiF), cesium fluoride (CsF), calcium fluoride (CaF₂), 8-quinolinolato-lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), an oxide of lithium (LiOₓ), or cesium carbonate. A rare earth metal or a compound of a rare earth metal, such as erbium fluoride (ErF₃) or ytterbium (Yb), can also be used. It is also possible to use a compound including a 1,3,4,6,7,8-tetrahydro-2H-pyrimido[1,2-a]pyrimidine skeleton, such as 1-(9,9′-spirobi[9H-fluoren]-2-yl)-1,3,4,6,7,8-hexahydro-2H-pyrimido[1,2-a]pyrimidine (abbreviation: 2hppSF), 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF), or 1,1′-pyridine-2,6-diyl-bis(1,3,4,6,7,8-hexahydro-2H-pyrimido[1,2-a]pyrimidine) (abbreviation: hpp2Py). To form the electron-injection layers (115, 115a, and 115b), two or more of the above materials may be mixed or stacked. Electride may also be used for the electron-injection layers (115, 115a, and 115b). Examples of the electride include a substance in which electrons are added at high concentration to calcium oxide-aluminum oxide. Any of the substances for forming the electron-transport layers (114, 114a, and 114b), which are given above, can also be used.

A mixed material in which an organic compound and an electron donor (donor) are mixed may also be used for the electron-injection layers (115, 115a, and 115b). Such a mixed material is excellent in an electron-injection property and an electron-transport property because electrons are generated in the organic compound by the electron donor. The organic compound here is preferably a material excellent in transporting the generated electrons; specifically, for example, the above-described electron-transport materials used for the electron-transport layers (114, 114a, and 114b), such as a metal complex and a heteroaromatic compound, can be used. As the electron donor, a substance showing an electron-donating property with respect to an organic compound can be used. Specifically, an alkali metal, an alkaline earth metal, and a rare earth metal are preferable, and lithium, cesium, magnesium, calcium, erbium, ytterbium, and the like are given as examples. In addition, an alkali metal oxide and an alkaline earth metal oxide are preferable, and lithium oxide, calcium oxide, barium oxide, and the like are given as examples. Alternatively, a Lewis base such as magnesium oxide can be used. Further alternatively, an organic compound such as tetrathiafulvalene (abbreviation: TTF) can be used. Alternatively, a stack of two or more of these materials may be used.

A mixed material in which an organic compound and a metal are mixed may also be used for the electron-injection layers (115, 115a, and 115b). The organic compound used here preferably has a LUMO level higher than or equal to −3.60 eV and lower than or equal to −2.30 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferable examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, or the like), a triazine ring, a bipyridine ring, or a terpyridine ring), and a heteroaromatic compound having a fused ring structure partly including a six-membered ring structure (e.g., a quinoline ring, a benzoquinoline ring, a quinoxaline ring, a dibenzoquinoxaline ring, or a phenanthroline ring). Since the materials are specifically described above, description thereof is omitted here.

As a metal used for the above mixed material, a transition metal that belongs to Group 5, Group 7, Group 9, or Group 11 or a material that belongs to Group 13 in the periodic table is preferably used, and examples include Ag, Cu, Al, and In. Here, the organic compound forms a singly occupied molecular orbital (SOMO) with the transition metal.

To amplify light obtained from the light-emitting layer 113b, for example, the optical path length between the second electrode 102 and the light-emitting layer 113b is preferably less than one fourth of the wavelength λ of light emitted from the light-emitting layer 113b. In that case, the optical path length can be adjusted by changing the thickness of the electron-transport layer 114b or the electron-injection layer 115b.

When the charge-generation layer 106 is provided between the two EL layers (103a and 103b) as in the light-emitting device in FIG. 10C, a structure in which a plurality of EL layers are stacked between the pair of electrodes (the structure is also referred to as a tandem structure) can be obtained.

### <Charge-Generation Layer>

The charge-generation layers (106, 106a, and 106b) have a function of injecting electrons into the EL layer 103a and injecting holes into the EL layer 103b when voltage is applied between the first electrode (anode) 101 and the second electrode (cathode) 102. The charge-generation layers (106, 106a, and 106b) may each be either a p-type layer in which an electron acceptor (acceptor) is added to a hole-transport material or an electron-injection buffer layer in which an electron donor (donor) is added to an electron-transport material. Alternatively, both of these structures may be stacked. Furthermore, an electron-relay layer may be provided between the p-type layer and the electron-injection buffer layer. Note that forming the charge-generation layers (106, 106a, and 106b) with the use of any of the above materials can inhibit an increase in driving voltage caused by the stack of the EL layers.

In the case where the charge-generation layers (106, 106a, and 106b) are each a p-type layer in which an electron acceptor is added to a hole-transport material, which is an organic compound, any of the materials described in this embodiment can be used as the hole-transport material. Examples of the electron acceptor include 7,7,8,8-tetracyano-2,3,5,6-tetrafluoroquinodimethane (abbreviation: F₄-TCNQ) and chloranil. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films including the respective materials may be used.

In the case where the charge-generation layers (106, 106a, and 106b) are each an electron-injection buffer layer in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, lithium (Li), cesium (Cs), magnesium (Mg), calcium (Ca), ytterbium (Yb), indium (In), lithium oxide (Li₂O), cesium carbonate, or the like is preferably used.

An alkali metal compound such as Liq may be used. An organic compound such as tetrathianaphthacene may be used as the electron donor. An organic compound including a 1,3,4,6,7,8-tetrahydro-2H-pyrimido[1,2-a]pyrimidine skeleton, such as 2hppSF, 2,7hpp2SF, or hpp2Py may be used as the electron donor. When any of these organic compounds is used as the electron donor, the electron-transport material to be combined with the electron donor is preferably an organic compound including a heteroaromatic ring having a phenanthroline ring, such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), or 2,2′-(1,3-phenylene)bis(9-phenyl-1,10-phenanthroline) (abbreviation: mPPhen2P), in which case driving voltage of the light-emitting device can be reduced.

When an electron-relay layer is provided between a p-type layer and an electron-injection buffer layer in each of the charge-generation layers (106, 106a, and 106b), the electron-relay layer includes at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer 106. Specifically, the LUMO level of the substance having an electron-transport property in the electron-relay layer is preferably higher than or equal to −5.00 eV, further preferably higher than or equal to −5.00 eV and lower than or equal to −3.00 eV. Note that as the substance having an electron-transport property in the electron-relay layer, a phthalocyanine-based material or a metal complex having a metal-oxygen bond and an aromatic ligand is preferably used.

Note that in terms of light extraction efficiency, the charge-generation layers (106, 106a, and 106b) preferably have a property of transmitting visible light (specifically, the charge-generation layers (106, 106a, and 106b) preferably have a visible light transmittance higher than or equal to 40%). The charge-generation layers (106, 106a, and 106b) function even if they have lower conductivity than the first electrode 101 and the second electrode 102.

Although FIG. 10C illustrates the structure in which two of the EL layers 103 are stacked, three or more EL layers may be stacked with charge-generation layers each provided between two adjacent EL layers.

### <Cap Layer>

Although not illustrated in FIGS. 10A to 10E, a cap layer may be provided over the second electrode 102 of the light-emitting device. For example, a material with a high refractive index can be used for the cap layer. When the cap layer is provided over the second electrode 102, extraction efficiency of light emitted through the second electrode 102 can be improved.

Specific examples of a material that can be used for the cap layer include 5,5′-diphenyl-2,2′-di-5H-[1]benzothieno[3,2-c]carbazole (abbreviation: BisBTc) and 4,4′,4″-(benzene-1,3,5-triyl)tri(dibenzothiophene) (abbreviation: DBT3P-II).

### <Substrate>

The light-emitting device described in this embodiment can be formed over a variety of substrates. Note that the type of the substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, and paper or a base material film including a fibrous material.

Examples of the glass substrate include a barium borosilicate glass substrate, an aluminoborosilicate glass substrate, and a soda lime glass substrate. Examples of the flexible substrate, the attachment film, and the base material film include plastics typified by polyethylene terephthalate (PET), polyethylene naphthalate (PEN), and polyether sulfone (PES), a synthetic resin such as an acrylic resin, polypropylene, polyester, polyvinyl fluoride, polyvinyl chloride, polyamide, polyimide, aramid, an epoxy resin, an inorganic vapor deposition film, and paper.

For manufacture of the light-emitting device in this embodiment, a gas phase method such as an evaporation method or a liquid phase method such as a spin coating method or an ink-jet method can be used. When an evaporation method is used, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the layers with various functions (the hole-injection layer 111, the hole-transport layer 112, the light-emitting layer 113, the electron-transport layer 114, and the electron-injection layer 115) included in the EL layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an ink-jet method, screen printing (stencil), offset printing (planography), flexography (relief printing), gravure printing, or micro-contact printing), or the like.

In the case where a film formation method such as the coating method or the printing method is employed, a high-molecular compound (e.g., an oligomer, a dendrimer, or a polymer), a middle-molecular compound (a compound between a low-molecular compound and a high-molecular compound with a molecular weight of 400 to 4000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the EL layer 103 of the light-emitting device described in this embodiment are not limited to the materials described in this embodiment, and other materials can be used in combination as long as the functions of the layers are fulfilled.

The structures described in this embodiment can be used in appropriate combination with any of the structures described in the other embodiments.

### Embodiment 4

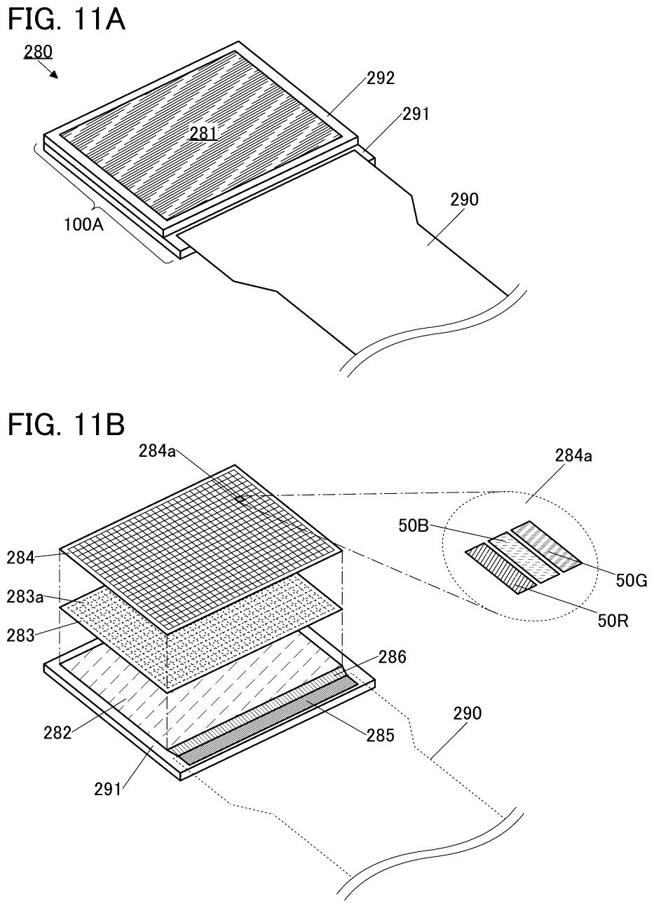

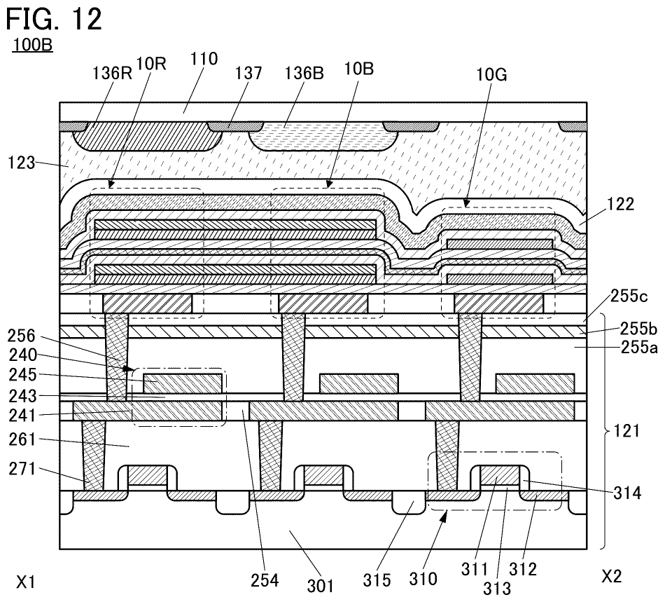

In this embodiment, display devices of embodiments of the present invention will be described with reference to FIGS. 11A and 11B and FIG. 12.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### [Display Module]

FIG. 11A is a perspective view of a display module 280. The display module 280 includes the display device 100A and an FPC 290.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 11B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 111B. The pixel 284a can employ any of the structures described in the above embodiments. FIG. 11B illustrates an example where a structure similar to that of the pixel 110 illustrated in FIG. 1A is employed.

The pixel circuit portion 283 includes a plurality of pixel circuits 283a arranged periodically.

Each of the pixel circuits 283a is a circuit that controls driving of a plurality of elements included in one pixel 284a. Each of the pixel circuits 283a can be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display device is achieved.

The circuit portion 282 includes a circuit for driving the pixel circuits 283a in the pixel circuit portion 283. For example, one or both of a gate line driver circuit and a source line driver circuit are preferably included. In addition, at least one of an arithmetic circuit, a memory circuit, a power supply circuit, and the like may be included.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; thus, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, and further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a device for VR such as an HMD or a glasses-type device for AR. For example, even in the case of a structure in which the display portion of the display module 280 is seen through a lens, pixels of the extremely-high-resolution display portion 281 included in the display module 280 are prevented from being seen when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Device 100B]

A display device 100B illustrated in FIG. 12 includes a substrate 301, the light-emitting device 10R, the light-emitting device 10G, the light-emitting device 10B, and transistors 310.

The subpixel 50R illustrated in FIG. 11B includes the light-emitting device 10R, the subpixel 50G includes the light-emitting device 10G, and the subpixel 50B includes the light-emitting device 10B.

The substrate 301 corresponds to the substrate 291 in FIGS. 11A and 11B. A stacked-layer structure including the substrate 301 and the components thereover up to an insulating layer 255c corresponds to the layer 121 including transistors in Embodiment 1.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is located between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided so as to be embedded in the substrate 301 between two of the transistors 310 that are adjacent to each other.

Furthermore, an insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

Note that a conductive layer surrounding the outer surface of the display portion 281 (or the pixel portion 284) is preferably provided in at least one layer of the conductive layers included in the layer 121 including transistors. The conductive layer can be referred to as a guard ring. By providing the conductive layer, elements such as a transistor and a light-emitting device can be inhibited from being broken by high voltage application due to electrostatic discharge (ESD) or charging caused by a step using plasma.

The insulating layer 255a is provided to cover the capacitor 240, the insulating layer 255b is provided over the insulating layer 255a, and the insulating layer 255c is provided over the insulating layer 255b. The light-emitting devices 10R, 10G, and 10B are provided over the insulating layer 255c.

The anodes of the light-emitting devices 10R, 10G, and 10B are each electrically connected to the one of the source and the drain of the transistor 310 through a plug 256 embedded in the insulating layers 243, 255a, 255b, and 255c, the conductive layer 241 embedded in the insulating layer 254, and the plug 271 embedded in the insulating layer 261. The surface of the insulating layer 255c that is in contact with the anode and the surface of the plug 256 that is in contact with the anode are level or substantially level with each other. Any of a variety of conductive materials can be used for the plugs.

The protective layer 122 is provided over the light-emitting devices 10R, 10G, and 10B. The substrate 124 is attached to the protective layer 122 with the resin layer 123. Embodiment 1 can be referred to for the details of the light-emitting devices and the components thereover up to the substrate 124. The substrate 124 corresponds to the substrate 292 in FIG. 11A.

As the protective layer 122, at least one of an insulating film, a semiconductor film, and a conductive film can be used. The protective layer 122 including an inorganic film can inhibit deterioration of the light-emitting devices by preventing oxidation of the cathode and inhibiting entry of impurities (e.g., moisture and oxygen) into the light-emitting devices, for example; thus, the reliability of the display device can be improved.

For the protective layer 122, an inorganic insulating film such as an oxide insulating film, a nitride insulating film, an oxynitride insulating film, or a nitride oxide insulating film can be used, for example. Specific examples of these inorganic insulating films are as listed in the description of the insulating layer 125. In particular, the protective layer 122 preferably includes a nitride insulating film or a nitride oxide insulating film, and further preferably includes a nitride insulating film.

For the resin layer 123, any of a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component-mixture-type resin may be used. An adhesive sheet or the like may be used.

For the substrate 124, glass, quartz, ceramic, sapphire, a resin, a metal, an alloy, a semiconductor, or the like can be used. The substrate through which light from the light-emitting devices is extracted is formed using a material that transmits the light. When a flexible material is used for the substrate 124, the flexibility of the display device can be increased. Furthermore, a polarizing plate or the like may be used. As described above, any of a variety of members can be used as the substrate.

For the substrate 124, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 124.

An inorganic insulating film is preferably used for the insulating layer 125. As the inorganic insulating film, a silicon nitride film, a silicon oxynitride film, a silicon oxide film, a silicon nitride oxide film, an aluminum oxide film, or an aluminum nitride film can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that a semiconductor layer of a transistor include a metal oxide (also referred to as an oxide semiconductor). That is, a transistor including a metal oxide in its channel formation region (hereinafter referred to as an OS transistor) is preferably used in the display device of this embodiment.

As examples of the oxide semiconductor having crystallinity, a c-axis aligned crystalline oxide semiconductor (CAAC-OS), a nanocrystalline oxide semiconductor (nc-OS), and the like are given.

Alternatively, a transistor including silicon in its channel formation region (a Si transistor) may be used. Examples of silicon include single crystal silicon, polycrystalline silicon, and amorphous silicon. In particular, a transistor including low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This enables simplification of an external circuit mounted on the display device and a reduction in costs of parts and mounting costs.

The OS transistor has much higher field-effect mobility than a transistor including amorphous silicon. In addition, the OS transistor has an extremely low leakage current between a source and a drain in an off state (hereinafter also referred to as off-state current), and electric charge accumulated in a capacitor that is connected in series to the transistor can be held for a long period. Furthermore, the power consumption of the display device can be reduced with the OS transistor.

To increase the emission luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher breakdown voltage between a source and a drain than a Si transistor; hence, high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor in the pixel circuit, a current flowing between the source and the drain can be set minutely in accordance with a change in gate-source voltage; hence, the amount of current flowing through the light-emitting device can be controlled. Consequently, the number of gray levels expressed by the pixel circuit can be increased.

Regarding saturation characteristics of current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the emission luminance of the light-emitting device can be stable.

As described above, by using OS transistors as the driving transistors included in the pixel circuits, it is possible to inhibit black-level degradation, increase the emission luminance, increase the number of gray levels, and suppress variations in light-emitting devices, for example.

The semiconductor layer preferably includes indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO). Alternatively, it is preferable to use indium oxide.

When the semiconductor layer is an In-M-Zn oxide, the atomic proportion of In is preferably greater than or equal to the atomic proportion of Min the In-M-Zn oxide. Examples of the atomic ratio of the metal elements in such an In-M-Zn oxide include In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the neighborhood of any of the above atomic ratios. Note that the neighborhood of the atomic ratio includes ±30% of an intended atomic ratio.

For example, when the atomic ratio is described as In:Ga:Zn=4:2:3 or a composition in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the neighborhood thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the neighborhood thereof, the case is included where the atomic proportion of Ga is greater than 0.1 and less than or equal to 2 and the atomic proportion of Zn is greater than 0.1 and less than or equal to 2 with the atomic proportion of In being 1.

The structures described in this embodiment can be used in appropriate combination with any of the structures described in the other embodiments.

### Embodiment 5

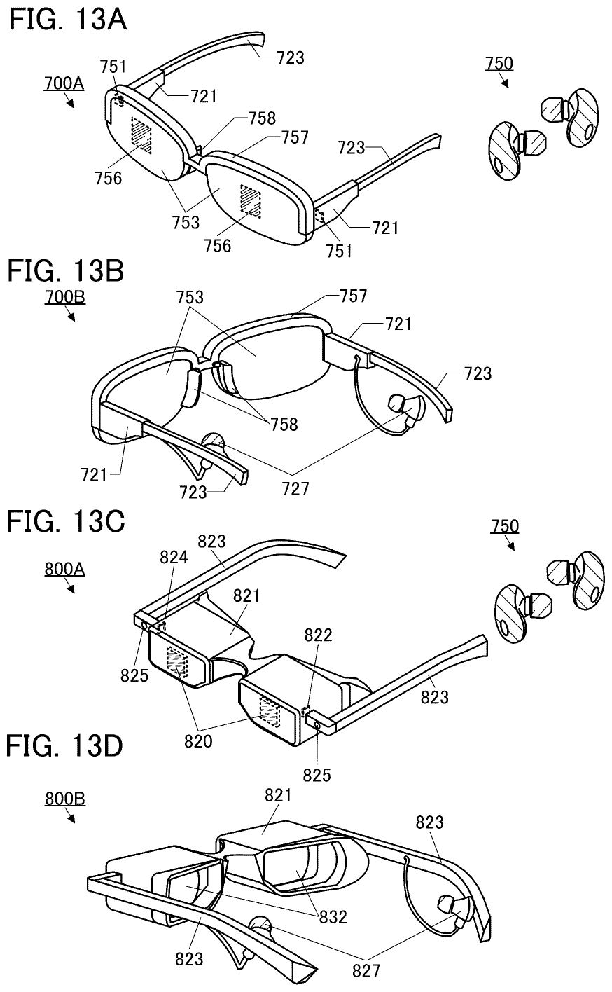

In this embodiment, electronic devices of embodiments of the present invention will be described with reference to FIGS. 13A to 13D, FIGS. 14A to 14F, and FIGS. 15A to 15G.

Electronic devices of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With such a display device having one or both of high definition and high resolution, the electronic device can provide higher realistic sensation, sense of depth, and the like in personal use such as portable use or home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device capable of being worn on a head will be described with reference to FIGS. 13A to 13D. The wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 13A and an electronic device 700B illustrated in FIG. 13B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic devices 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic devices 700A and 700B are capable of performing AR display.

In the electronic devices 700A and 700B, a camera capable of capturing images of the front side may be provided as the image capturing portion. Furthermore, when the electronic devices 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic devices 700A and 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables executing various types of processing. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device. One or both of an inorganic semiconductor and an organic semiconductor can be used for an active layer of the photoelectric conversion device.

An electronic device 800A illustrated in FIG. 13C and an electronic device 800B illustrated in FIG. 13D each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic devices are capable of performing ultrahigh-resolution display. Such electronic devices provide a high sense of immersion to the user.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR.

The user who wears the electronic device 800A or 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are located optimally in accordance with the positions of the user's eyes. Moreover, the electronic devices 800A and 800B preferably include a mechanism for adjusting focus by changing the distance between the lenses 832 and the display portions 820.

The electronic device 800A or 800B can be mounted on the user's head with the wearing portions 823. FIG. 13C and the like illustrate examples where the wearing portion 823 has a shape like a temple (also referred to as a joint or the like) of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic device 800A.

The electronic devices 800A and 800B may each include an input terminal (also referred to as an input portion). To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 13A has a function of transmitting information to the earphones 750 with the wireless communication function. For another example, the electronic device 800A in FIG. 13C has a function of transmitting information to the earphones 750 with the wireless communication function.

The electronic device may include an earphone portion. The electronic device 700B in FIG. 13B includes earphone portions 727. For example, the earphone portion 727 can be connected to the control portion by wire. Part of a wiring that connects the earphone portion 727 and the control portion may be located inside the housing 721 or the wearing portion 723.

Similarly, the electronic device 800B in FIG. 13D includes earphone portions 827. For example, the earphone portion 827 can be connected to the control portion 824 by wire. Part of a wiring that connects the earphone portion 827 and the control portion 824 may be located inside the housing 821 or the wearing portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 700A and 700B) and the goggles-type device (e.g., the electronic devices 800A and 800B) are preferable as the electronic device of one embodiment of the present invention.

The electronic device of one embodiment of the present invention can transmit information to earphones by wire or wirelessly.

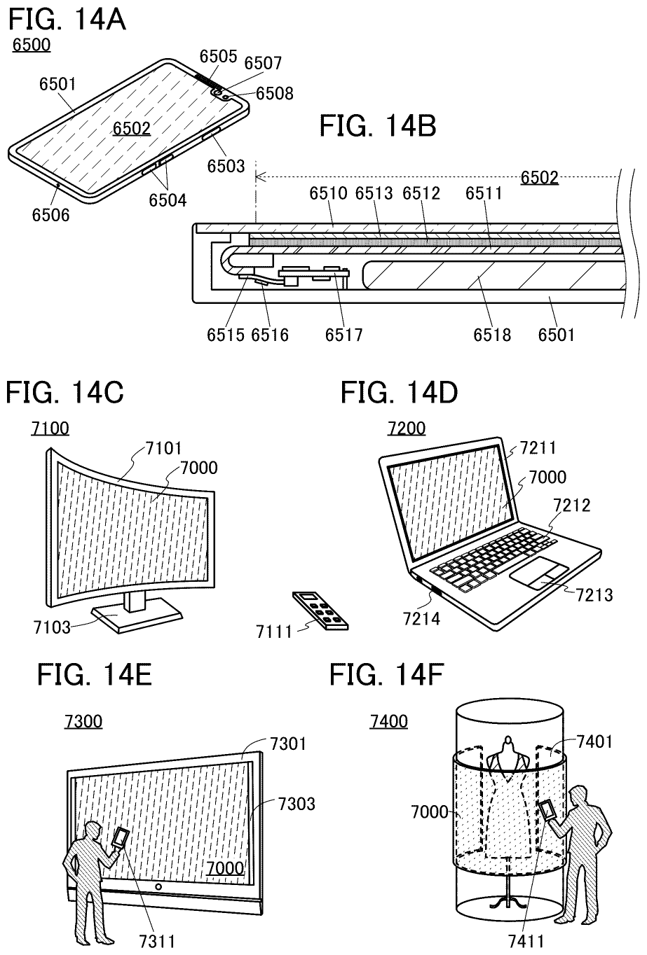

An electronic device 6500 illustrated in FIG. 14A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 14B is a schematic cross-sectional view including an end portion of the housing 6501 closer to the microphone 6506.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used for the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 14C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 14C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 14D illustrates an example of a notebook personal computer. The notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIGS. 14E and 14F illustrate examples of digital signage that can be used for store windows, showcases, and the like.

Digital signage 7300 illustrated in FIG. 14E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 14F illustrates digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIGS. 14E and 14F.

A larger area of the display portion 7000 allows a larger amount of information to be provided at a time. The larger display portion 7000 attracts more attention, so that the effectiveness of the advertisement can be increased, for example.

Specifically, in the case where the display device of one embodiment of the present invention is used for the digital signage 7400 in FIG. 14F that displays advertisements and the like, the display device being a light-transmitting panel can increase the flexibility of representation in advertising. A light-transmitting display device can be manufactured, for example, by using a wiring and a support member each of which is formed of a conductive film that transmits visible light and adjusting the distance between pixel electrodes.

The use of the tandem light-emitting device of one embodiment of the present invention in addition to the wiring and the support member each of which is formed of the conductive film that transmits visible light can increase the luminance per pixel. That is, favorable display can be performed even when the aperture ratio of the display device is reduced; thus, the light-transmitting property of the display portion of the display device can be increased. Accordingly, such a structure is suitably used in the light-transmitting display device of one embodiment of the present invention.

As illustrated in FIGS. 14E and 14F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

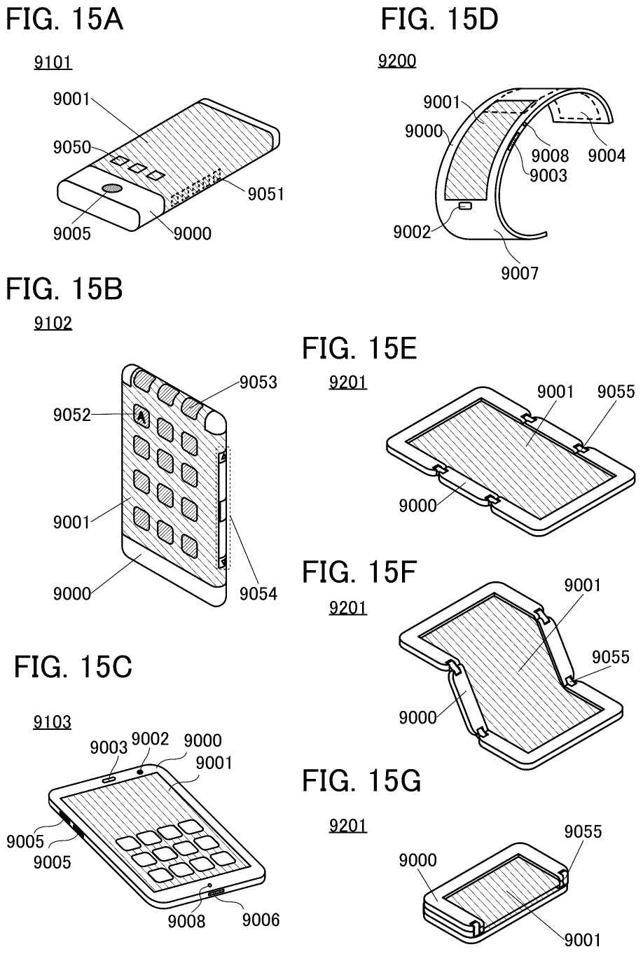

Electronic devices illustrated in FIGS. 15A to 15G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, a smell, or infrared rays), a microphone 9008, and the like.

The electronic devices illustrated in FIGS. 15A to 15G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices in FIGS. 15A to 15G will be described in detail below.

FIG. 15A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 15A illustrates an example where three icons 9050 are displayed. Furthermore, information 9051 indicated by dashed rectangles can be displayed on another surface of the display portion 9001. Examples of the information 9051 include notification of reception of an e-mail, a social networking service (SNS; also referred to as social media) message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 15B is a perspective view of a portable information terminal 9102. The portable information terminal 9102 has a function of displaying information on three or more surfaces of the display portion 9001. Here, an example in which information 9052, information 9053, and information 9054 are displayed on different surfaces is described. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 15C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 15D is a perspective view of a watch-type portable information terminal 9200. The portable information terminal 9200 can be used as a Smartwatch (registered trademark), for example. The portable information terminal 9200 may include the operation key 9005 as a button for operation on the left side surface of the housing 9000 and the sensor 9007 on the bottom surface of the housing 9000. Although the housing 9000 having a curved bangle shape is illustrated as an example, a belt or the like may be used in combination with the housing 9000 to make the portable information terminal 9200 wearable. The display surface of the display portion 9001 is curved, and an image can be displayed on the curved display surface. A power storage device 9004 may have a curved shape along the housing 9000. The power storage device 9004 has flexibility and can be bent in accordance with a change in shape when the user puts on or takes off the portable information terminal 9200. Note that a charging control IC connected to the power storage device 9004 may be provided. Furthermore, for example, mutual communication between the portable information terminal 9200 and a headset capable of wireless communication can be performed, and thus hands-free calling is possible. The portable information terminal 9200 can perform mutual data transmission wirelessly with another information terminal and can be charged with wireless power feeding. Note that the connection terminal 9006 may be provided in the housing 9000 so that data transmission and charging operation may be performed by wire.

FIGS. 15E to 15G are perspective views of a foldable portable information terminal 9201. FIG. 15E is a perspective view illustrating the portable information terminal 9201 that is opened. FIG. 15G is a perspective view illustrating the portable information terminal 9201 that is folded. FIG. 15F is a perspective view illustrating the portable information terminal 9201 that is shifted from one of the states in FIGS. 15E and 15G to the other. The portable information terminal 9201 is highly portable when folded. When the portable information terminal 9201 is opened, a seamless large display region is highly browsable. The display portion 9001 of the portable information terminal 9201 is supported by three of the housings 9000 joined together by hinges 9055. The display portion 9001 can be folded with a radius of curvature greater than or equal to 0.1 mm and less than or equal to 150 mm, for example.

The structures described in this embodiment can be used in appropriate combination with any of the structures described in the other embodiments.

### Embodiment 6

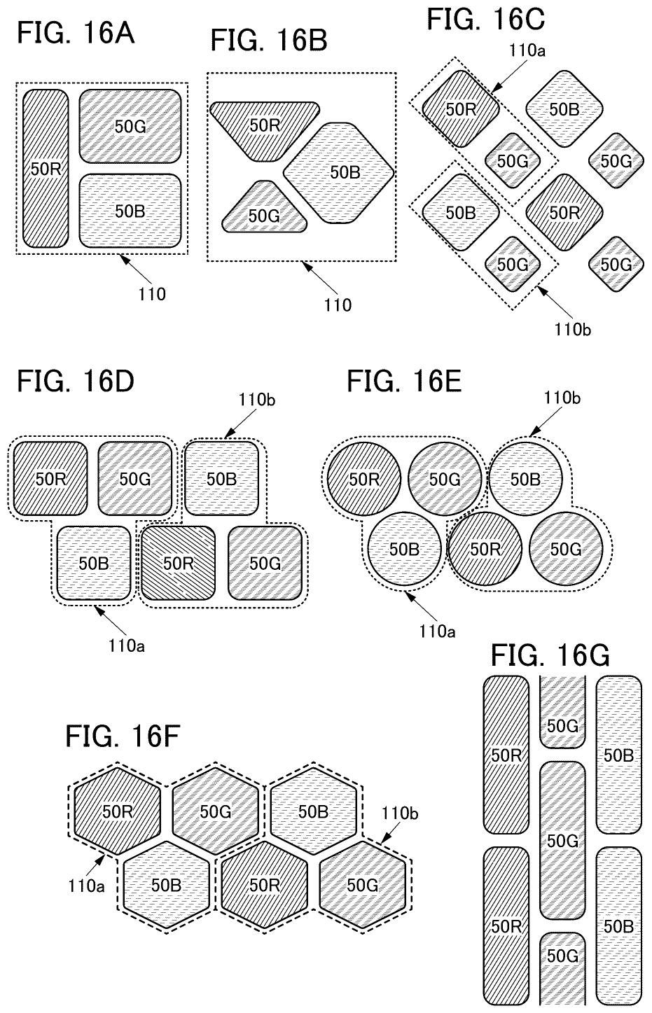

In this embodiment, the light-emitting apparatus of one embodiment of the present invention will be described with reference to FIGS. 16A to 16G.

### [Pixel Layout]

In this embodiment, pixel layouts different from that in FIG. 1A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

In this embodiment, the top surface shapes of the subpixels shown in the diagrams correspond to top surface shapes of light-emitting regions.

Examples of a top surface shape of the subpixel include polygons such as a triangle, a tetragon (including a rectangle and a square), and a pentagon; these polygons with rounded corners; an ellipse; and a circle.

The circuit constituting the subpixel is not necessarily placed within the dimensions of the subpixel illustrated in the diagrams and may be placed outside the subpixel.

The pixel 110 illustrated in FIG. 16A employs S-stripe arrangement. The pixel 110 illustrated in FIG. 16A includes three subpixels, the subpixel 50R, the subpixel 50G, and the subpixel 50B.

The pixel 110 illustrated in FIG. 16B includes the subpixel 50R whose top surface has a rough trapezoidal or rough triangle shape with rounded corners, the subpixel 50G whose top surface has a rough trapezoidal or rough triangle shape with rounded corners, and the subpixel 50B whose top surface has a rough tetragonal or rough hexagonal shape with rounded corners. The subpixel 50R has a larger light-emitting area than the subpixel 50G. In this manner, the shapes and sizes of the subpixels can be determined independently. For example, the size of a subpixel including a light-emitting device with higher reliability can be smaller.

Pixels 110a and 110b illustrated in FIG. 16C employ PenTile arrangement. FIG. 16C illustrates an example in which the pixels 110a including the subpixels 50R and 50G and the pixels 110b including the subpixels 50G and 50B are alternately arranged.

The pixels 110a and 110b illustrated in FIGS. 16D to 16F employ delta arrangement. The pixel 110a includes two subpixels (the subpixels 50R and 50G) in the upper row (the first row) and one subpixel (the subpixel 50B) in the lower row (the second row). The pixel 110b includes one subpixel (the subpixel 50B) in the upper row (the first row) and two subpixels (the subpixels 50R and 50G) in the lower row (the second row).

FIG. 16D illustrates an example where the top surface of each subpixel has a rough tetragonal shape with rounded corners. FIG. 16E illustrates an example where the top surface of each subpixel is circular. FIG. 16F illustrates an example where the top surface of each subpixel has a rough hexagonal shape with rounded corners.

In FIG. 16F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 50R, the subpixel 50R is surrounded by three subpixels 50G and three subpixels 50B that are alternately arranged.

FIG. 16G illustrates an example where subpixels of different colors are arranged in a zigzag manner. Specifically, the positions of the top sides of two subpixels arranged in the row direction (e.g., the subpixels 50R and 50G or the subpixels 50G and 50B) are not aligned in the top view.

As described above, the pixel composed of the subpixels each including the light-emitting device can employ any of a variety of layouts in the light-emitting apparatus of one embodiment of the present invention.

This embodiment can be combined as appropriate with the other embodiments. In this specification, in the case where a plurality of structure examples are shown in one embodiment, the structure examples can be combined as appropriate.

This application is based on Japanese Patent Application Serial No. 2024-081012 filed with Japan Patent Office on May 17, 2024, the entire contents of which are hereby incorporated by reference.

What is claimed is:

1. A display device comprising:
a first subpixel, a second subpixel, and a third subpixel emitting light of different colors,
wherein the first subpixel comprises a first coloring layer and a first light-emitting device,
wherein the second subpixel comprises a second coloring layer and a second light-emitting device,
wherein the third subpixel comprises a third light-emitting device,
wherein the first light-emitting device comprises a first light-emitting layer and a second light-emitting layer between a pair of electrodes and comprises a first intermediate layer between the first light-emitting layer and the second light-emitting layer,
wherein the first light-emitting layer and the second light-emitting layer each comprise a first layer comprising a blue-light-emitting substance and a second layer comprising a red-light-emitting substance,
wherein the second light-emitting device comprises a third light-emitting layer and a fourth light-emitting layer between a pair of electrodes and comprises a second intermediate layer between the third light-emitting layer and the fourth light-emitting layer,
wherein the third light-emitting layer and the fourth light-emitting layer each comprise a third layer comprising a blue-light-emitting substance and a fourth layer comprising a red-light-emitting substance,
wherein the third light-emitting device comprises a fifth light-emitting layer and a sixth light-emitting layer between a pair of electrodes and comprises a third intermediate layer between the fifth light-emitting layer and the sixth light-emitting layer, and
wherein the fifth light-emitting layer and the sixth light-emitting layer each comprise a green-light-emitting substance.

2. The display device according to claim 1,
wherein the first intermediate layer and the second intermediate layer each comprise an organic compound and an alkali metal or an alkaline earth metal.

3. The display device according to claim 1,
wherein the first intermediate layer and the second intermediate layer comprise the same organic compound and the same alkali metal or the same alkaline earth metal.

4. A display device comprising:
a first subpixel and a second subpixel emitting light of different colors,
wherein the first subpixel comprises a first coloring layer and a first light-emitting device,
wherein the second subpixel comprises a second coloring layer and a second light-emitting device,
wherein the first light-emitting device comprises a first light-emitting layer, a second light-emitting layer, a third light-emitting layer, a fourth light-emitting layer, and a first intermediate layer between a pair of electrodes,
wherein the first light-emitting layer is in contact with the second light-emitting layer,
wherein the third light-emitting layer is in contact with the fourth light-emitting layer,
wherein the first intermediate layer is between the first light-emitting layer and the third light-emitting layer and is between the second light-emitting layer and the fourth light-emitting layer,
wherein the second light-emitting device comprises a fifth light-emitting layer, a sixth light-emitting layer, a seventh light-emitting layer, an eighth light-emitting layer, and a second intermediate layer between a pair of electrodes,
wherein the fifth light-emitting layer is in contact with the sixth light-emitting layer,
wherein the seventh light-emitting layer is in contact with the eighth light-emitting layer,
wherein the second intermediate layer is between the fifth light-emitting layer and the seventh light-emitting layer and is between the sixth light-emitting layer and the eighth light-emitting layer,
wherein the first light-emitting layer and the fifth light-emitting layer comprise a first light-emitting substance,
wherein the second light-emitting layer and the sixth light-emitting layer comprise a second light-emitting substance,
wherein the third light-emitting layer and the seventh light-emitting layer comprise the first light-emitting substance, and
wherein the fourth light-emitting layer and the eighth light-emitting layer comprise the second light-emitting substance.

5. The display device according to claim 4,
wherein the first light-emitting substance is a blue-light-emitting substance, and
wherein the second light-emitting substance is a red-light-emitting substance.

6. The display device according to claim 4,
wherein an emission wavelength of one of the first light-emitting substance and the second light-emitting substance is greater than or equal to 1.18 times and less than or equal to 1.88 times an emission wavelength of the other of the first light-emitting substance and the second light-emitting substance.

7. The display device according to claim 4,
wherein the first light-emitting substance is a fluorescent substance, and
wherein the second light-emitting substance is a phosphorescent substance.

8. The display device according to claim 4,
wherein the first light-emitting substance is a fluorescent substance,
wherein the second light-emitting substance is a phosphorescent substance,
wherein the first light-emitting layer comprises a first host material, and
wherein a T₁ level of the first host material and a T₁ level of the first light-emitting substance are higher than a T₁ level of the second light-emitting substance.

9. The display device according to claim 4,
wherein the first intermediate layer and the second intermediate layer each comprise an organic compound and an alkali metal or an alkaline earth metal.

10. The display device according to claim 4,
wherein the first intermediate layer and the second intermediate layer comprise the same organic compound and the same alkali metal or the same alkaline earth metal.

11. A display device comprising:
a first subpixel, a second subpixel, and a third subpixel emitting light of different colors,
wherein the first subpixel comprises a first coloring layer and a first light-emitting device,
wherein the second subpixel comprises a second coloring layer and a second light-emitting device,
wherein the third subpixel comprises a third light-emitting device,
wherein the first light-emitting device comprises a first light-emitting layer, a second light-emitting layer, a third light-emitting layer, a fourth light-emitting layer, and a first intermediate layer between a pair of electrodes,
wherein the first light-emitting layer is in contact with the second light-emitting layer,
wherein the third light-emitting layer is in contact with the fourth light-emitting layer,
wherein the first intermediate layer is between the first light-emitting layer and the third light-emitting layer and is between the second light-emitting layer and the fourth light-emitting layer,
wherein the second light-emitting device comprises a fifth light-emitting layer, a sixth light-emitting layer, a seventh light-emitting layer, an eighth light-emitting layer, and a second intermediate layer between a pair of electrodes,
wherein the fifth light-emitting layer is in contact with the sixth light-emitting layer,
wherein the seventh light-emitting layer is in contact with the eighth light-emitting layer,
wherein the second intermediate layer is between the fifth light-emitting layer and the seventh light-emitting layer and is between the sixth light-emitting layer and the eighth light-emitting layer,
wherein the third light-emitting device comprises a ninth light-emitting layer, a tenth light-emitting layer, and a third intermediate layer between a pair of electrodes,
wherein the third intermediate layer is between the ninth light-emitting layer and the tenth light-emitting layer,
wherein the first light-emitting layer and the fifth light-emitting layer comprise a first light-emitting substance,
wherein the second light-emitting layer and the sixth light-emitting layer comprise a second light-emitting substance,
wherein the third light-emitting layer and the seventh light-emitting layer comprise the first light-emitting substance,
wherein the fourth light-emitting layer and the eighth light-emitting layer comprise the second light-emitting substance, and
wherein the ninth light-emitting layer and the tenth light-emitting layer comprise a third light-emitting substance.

12. The display device according to claim 11,
wherein the first light-emitting substance is a blue-light-emitting substance,
wherein the second light-emitting substance is a red-light-emitting substance, and
wherein the third light-emitting substance is a green-light-emitting substance.

13. The display device according to claim 11,
wherein the first light-emitting substance is a fluorescent substance, and
wherein the second light-emitting substance is a phosphorescent substance.

14. The display device according to claim 11,
wherein the first light-emitting substance is a fluorescent substance,
wherein the second light-emitting substance is a phosphorescent substance,
wherein the first light-emitting layer comprises a first host material, and
wherein a T₁ level of the first host material and a T₁ level of the first light-emitting substance are higher than a T₁ level of the second light-emitting substance.

15. The display device according to claim 11,
wherein the first intermediate layer and the second intermediate layer each comprise an organic compound and an alkali metal or an alkaline earth metal.

16. The display device according to claim 11,
wherein the first intermediate layer and the second intermediate layer comprise the same organic compound and the same alkali metal or the same alkaline earth metal.
